(19) United States
(12) Patent Application Publication
(10) Pub. No.: US 2012/0240858 A1
(43) Pub. Date: Sep. 27, 2012

(54) SUBSTRATE PROCESSING APPARATUS AND SOLID RAW MATERIAL REPLENISHING METHOD

(75) Inventors: Tomoshi TANIYAMA, Toyama (JP); Goki KOYAMA, Tokyo (JP)

(73) Assignees: KITZ SCT CORPORATION, Tokyo (JP); HITACHI KOKUSAI ELECTRIC INC., Tokyo (JP)

(21) Appl. No.: 13/425,430

(22) Filed: Mar. 21, 2012

(30) Foreign Application Priority Data
Mar. 22, 2011 (JP) 2011-062454
Jan. 20, 2012 (JP) 2012-010134

(51) Int. Cl. C23C 16/448; F17D 3/00

(52) U.S. Cl. 118/726; 137/1

(57) ABSTRACT

Disclosed is a substrate processing apparatus that includes: a processing chamber that accommodates a substrate; and a raw material supply system that sublimates a solid raw material to generate a gas raw material used for processing of the substrate, and supplies the generated gas raw material to the processing chamber. The raw material supply system includes: a solid raw material container that stores the solid raw material; a first piping connected between the solid raw material container and the processing chamber; and a second piping connected with the solid raw material container and equipped with an attachment portion to which a raw material replenishing container that holds the solid raw material for replenishment is attached.

### CROSS-REFERENCE TO RELATED APPLICATION

This application claims priority under 35 USC 119 from Japanese Patent Application No. 2011-62454 filed on Mar. 22, 2011 and Japanese Patent Application No. 2012-10134 filed on Jan. 20, 2012, the disclosures of which are incorporated by reference herein.

### BACKGROUND

1. Technical Field

The present invention relates to a substrate processing apparatus and a solid raw material replenishing method, and more particularly, to a substrate processing apparatus for processing a substrate, such as a semiconductor wafer, and a solid raw material replenishing method that replenishes the substrate processing apparatus with a solid raw material.

2. Related Art

When a thin film is formed on a surface of a semiconductor wafer, a substrate processing apparatus having a processing chamber having a semiconductor wafer placing part therein is used. A raw material supply system that supplies a source gas or source gases is connected to the processing chamber, the source gas or the source gases are supplied into the processing chamber from the raw material supply system, and a thin film is formed on the semiconductor wafer.

When a substance is used that is a solid at room temperature like GaCl₃ as a raw material in formation of a thin film using the substrate processing apparatus, a solid raw material tank that stores a solid raw material is provided, the solid raw material is sublimated within the solid raw material tank, and the sublimated gas raw material is supplied into the processing chamber as a source gas through piping of the raw material supply system.

In the related art, if the solid raw material within the solid raw material tank is exhausted, removing the solid raw material tank that has become empty from the piping of the raw material supply system to exchange the empty tank for a solid raw material tank fully filled with the solid raw material is performed.

In such a related-art technique, when the solid raw material tank that has become empty is removed from the piping of the raw material supply system for exchange of the solid raw material tank, there is a problem in that the piping of the raw material supply system is opened to the atmosphere, moisture or the like in the atmosphere adheres to the inside of the piping, and purge time for removing the moisture becomes long.

Thus, a technique capable of replenishing the solid raw material tank with a raw material without removing the solid raw material tank is developed (refer to Japanese Patent Application Laid-Open (JP-A) No. 2010-40695).

In this technique, there is provided an apparatus equipped with a raw material container that holds a solid raw material, a raw material replenishing container that is connected with the raw material container and replenishes the solid raw material to the raw material container, a heater that heats the raw material replenishing container, and a pressure adjusting means capable of adjusting the pressure inside the raw material container and the raw material replenishing container. This apparatus is used to reduce the pressure inside the raw material replenishing container, heat the inside of the raw material replenishing container to sublimate the solid raw material and transform solid raw material into a gas raw material, reducing the pressure inside the raw material container to trap the gas raw material from the raw material replenishing container in the raw material container, and lowering the temperature inside the raw material replenishing container. By repeating this procedure by a predetermined number of times, the raw material container is replenished with the solid raw material from the raw material replenishing container.

Additionally, the following apparatus including a solid raw material storage portion that stores a solid raw material, a solid raw material receiving member that melts the solid raw material supplied from the solid raw material storage portion to obtain a liquid raw material, and a vaporizing chamber that communicates with the solid raw material receiving member and vaporizes the liquid raw material supplied from the solid raw material receiving member is also suggested in order to heat and evaporate the solid raw material to obtain a source gas for film formation (refer to Japanese Patent Application Laid-Open (JP-A) No. 2010-144221).

However, in such a solid raw material replenishing technique, the configuration of the apparatuses becomes complicated, and the replenishing methods also become complicated.

### SUMMARY

A main object of the present invention is to provide a substrate processing apparatus capable of replenishing a solid raw material with simple configuration, and a solid raw material replenishing method capable of simply replenishing a solid raw material.

According to a first aspect of the present invention, there is provided a substrate processing apparatus, including:

a processing chamber that accommodates a substrate; and

a raw material supply system that sublimates a solid raw material to generate a gas raw material used for processing of the substrate, and supplies the generated gas raw material to the processing chamber, wherein

the raw material supply system includes:

a solid raw material container that stores the solid raw material;

a first piping connected between the solid raw material container and the processing chamber; and

a second piping connected with the solid raw material container and equipped with an attachment portion to which a raw material replenishing container that holds the solid raw material for replenishment is attached.

According to a second aspect of the present invention, there is provided a substrate processing apparatus, including:

a processing chamber that accommodates a substrate; and

a raw material supply system that sublimates a solid raw material to generate a gas raw material used for processing of the substrate, and supplies the generated gas raw material to a processing chamber; wherein

the raw material supply system includes:

a solid raw material container that stores the solid raw material;

a first piping connected between the solid raw material container and the processing chamber;

an attachment portion in which a raw material replenishing container that holds the solid raw material for replenishment is attached to the solid raw material container;

a raw material replenishing container purge gas introducing portion attachment portion to which a purge gas introducing portion of a raw material replenishing container that introduces purge gas into the raw material replenishing container is attached; and

a raw material replenishing container purge gas discharge portion attachment portion to which a purge gas discharge portion of the raw material replenishing container that discharges purge gas from the raw material replenishing container is attached; and

a control unit configured to control the purge gas introducing portion and the purge gas discharge portion so as to introduce the purge gas into the raw material replenishing container from the purge gas introducing portion of the raw material replenishing container and discharge the purge gas from the purge gas discharge portion of the raw material replenishing container when the raw material replenishing container is attached to the attachment portion in order to replenish the solid raw material to the solid raw material container from the raw material replenishing container, the purge gas introducing portion of the raw material replenishing container is attached to the raw material replenishing container purge gas introducing portion attachment portion, and the purge gas discharge portion of the raw material replenishing container is attached to the raw material replenishing container purge gas discharge portion attachment portion.

According to a third aspect of the present invention, there is provided a solid raw material replenishing method, including:

attaching a raw material replenishing container to an attachment portion of a raw material supply system; wherein the raw material supply system sublimates a solid raw material to generate a gas raw material used for processing of a substrate, and supplies the generated gas raw material to a processing chamber that processes the substrate, and wherein the raw material supply system includes: a solid raw material container that stores the solid raw material; a first piping connected between the solid raw material container and the processing chamber; a second piping connected with the solid raw material container and equipped with an attachment portion to which the raw material replenishing container that holds the solid raw material for replenishment is attached; a third piping connected between the second piping and an evacuation means; a fourth piping connected with the second piping to introduce purge gas; a first valve connected in the middle of the third piping; and a second valve connected in the middle of the fourth piping;

closing the second valve, opening the first valve, and vacuuming the inside of the second piping with the evacuation unit, in a state where the raw material replenishing container is attached to the attachment portion;

thereafter closing the first valve, opening the second valve, and introducing the purge gas within the second piping; and

thereafter replenishing the solid raw material via the second piping to the solid raw material container from the raw material replenishing container.

According to a fourth aspect of the present invention, there is provided a solid raw material replenishing method including:

attaching a raw material replenishing container to an attachment portion of a raw material supply system, wherein the raw material supply system sublimates a solid raw material to generate a gas raw material used for processing of the substrate, and supplies the generated gas raw material to a processing chamber that processes the substrate; and wherein the raw material supply system includes: a solid raw material container that stores the solid raw material; a first piping connected between the solid raw material container and the processing chamber; an attachment portion in which a raw material replenishing container that holds the solid raw material for replenishment is attached to the solid raw material container; a raw material replenishing container purge gas introducing portion attachment portion to which a purge gas introducing portion of the raw material replenishing container that introduces purge gas into the raw material replenishing container is attached; and a raw material replenishing container purge gas discharge portion attachment portion to which a purge gas discharge portion of the raw material replenishing container that discharges purge gas from the raw material replenishing container is attached;

attaching a purge gas introducing portion of the raw material replenishing container that introduces purge gas into the raw material replenishing container to a raw material replenishing container purge gas introducing portion attachment portion of the raw material supply system, and

attaching a purge gas discharge portion of the raw material replenishing container that discharges purge gas from the raw material replenishing container to a raw material replenishing container purge gas discharge portion attachment portion of the raw material supply system;

thereafter introducing the purge gas into the raw material replenishing container from the purge gas introducing portion of the raw material replenishing container, and discharging the purge gas from the purge gas discharge portion of the raw material replenishing container; and

thereafter replenishing the solid raw material to the solid raw material container from the raw material replenishing container in a state where the raw material replenishing container is attached to the attachment portion.

### BRIEF DESCRIPTION OF THE DRAWINGS

An exemplary embodiment of the present invention will be described in detail based on the following figures, wherein:

FIG. 1 is a schematic perspective view for explaining a configuration of a substrate processing apparatus to be suitably used in preferable embodiments of the present invention;

FIG. 2 is a schematic configuration view for explaining an example of a processing furnace of a substrate processing apparatus to be suitably used in a preferable first embodiment of the present invention, and a raw material supply system, an exhaust system, or the like that accompanies the processing furnace, and is a schematic configuration view showing a processing furnace portion in a schematic longitudinal section;

FIG. 3 is a schematic transverse sectional view for explaining an internal structure of the processing furnace shown in FIG. 2;

FIG. 4 is a schematic view for explaining a nozzle of the processing furnace shown in

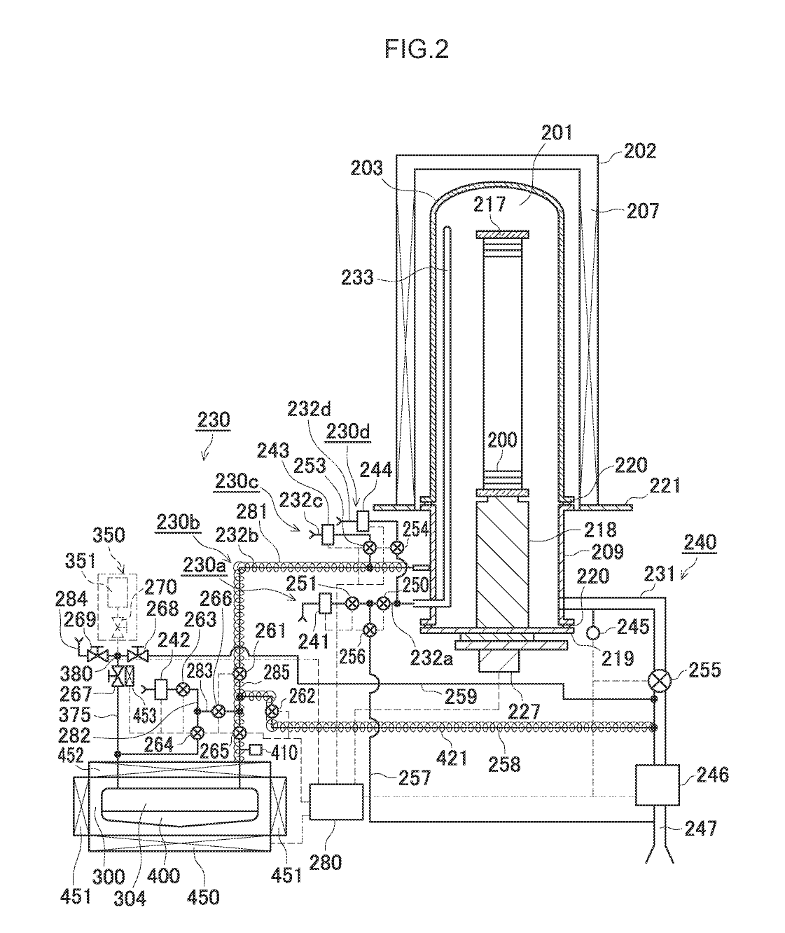

FIG. 2;

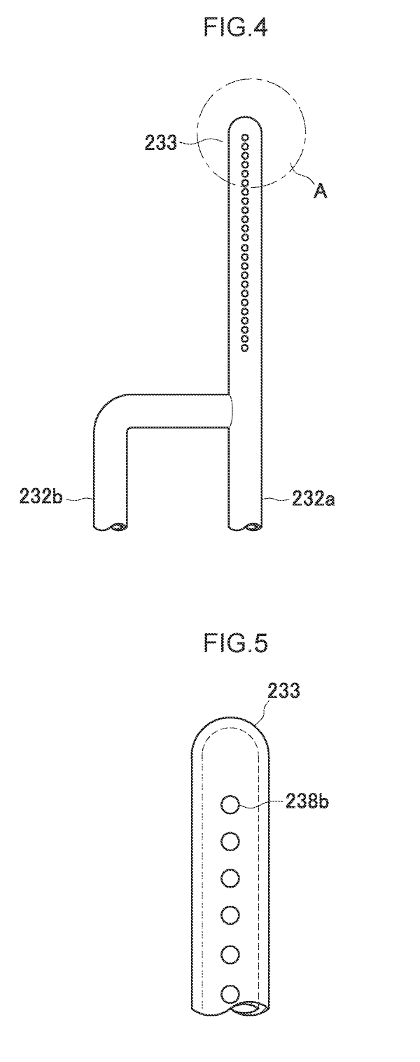

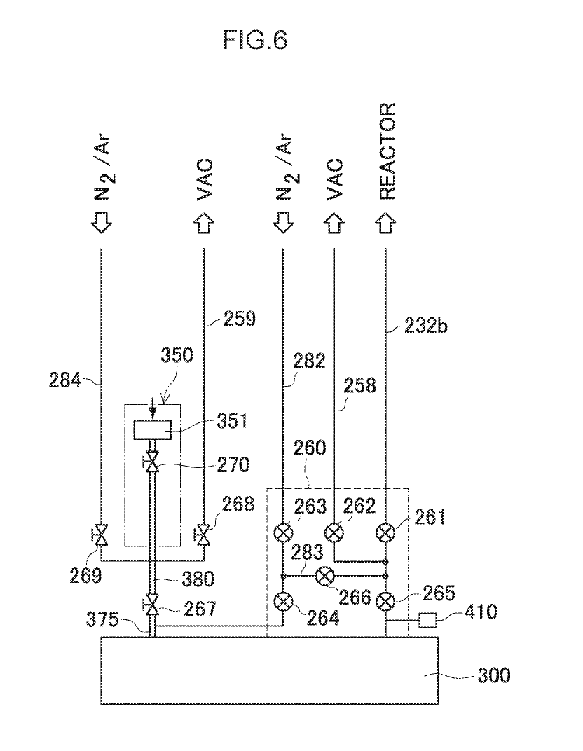

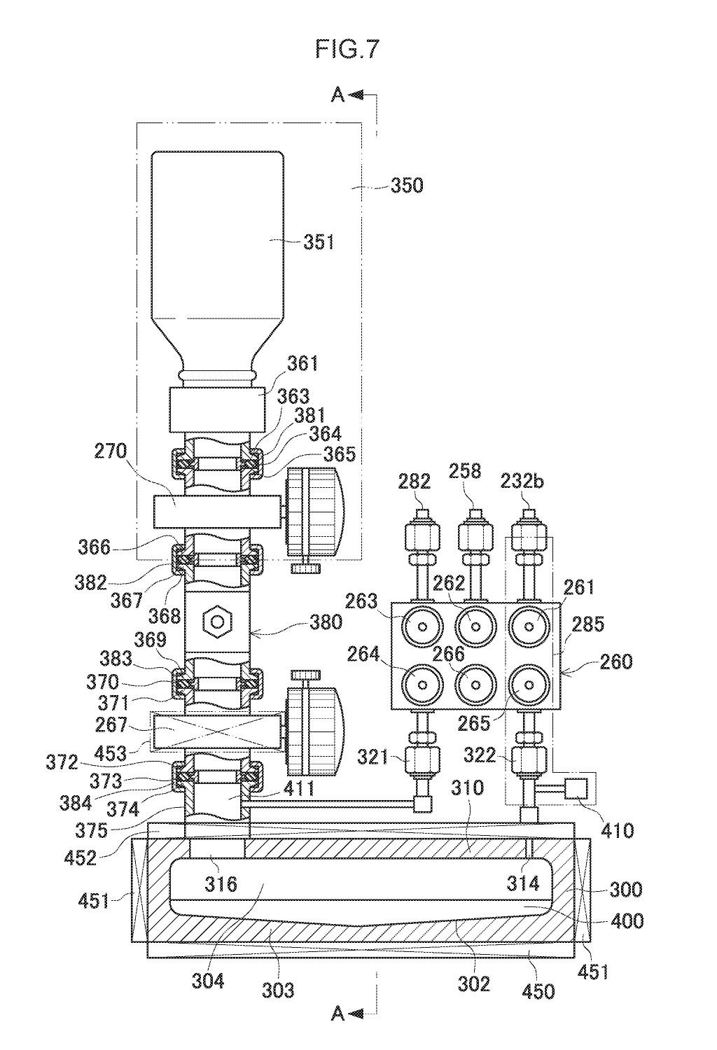

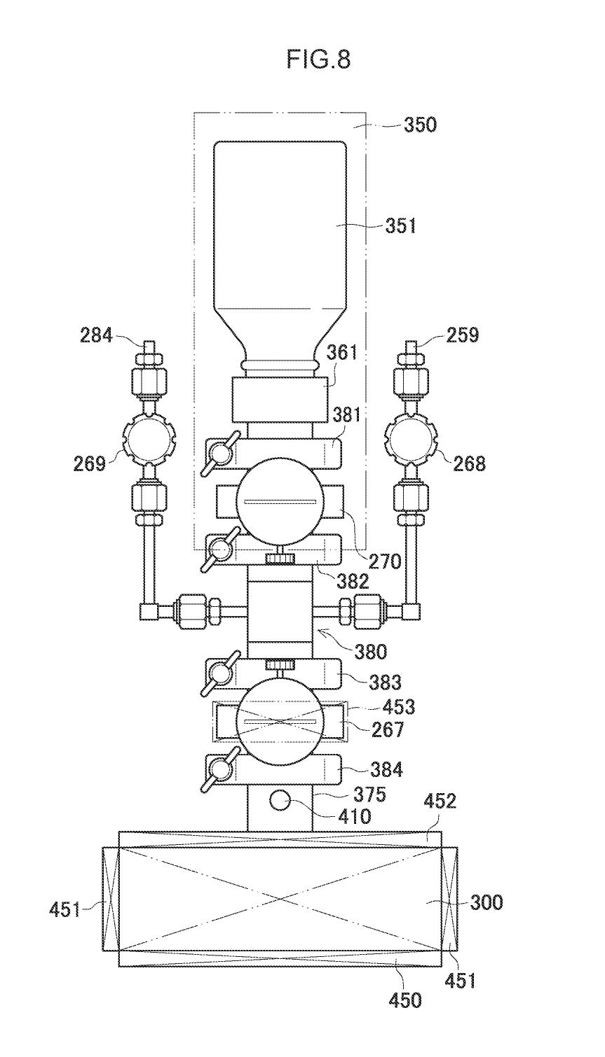

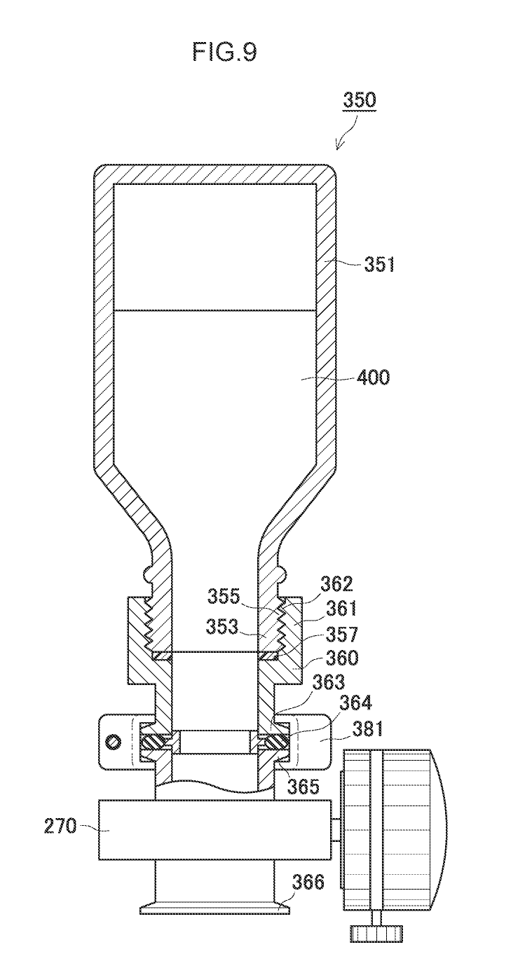

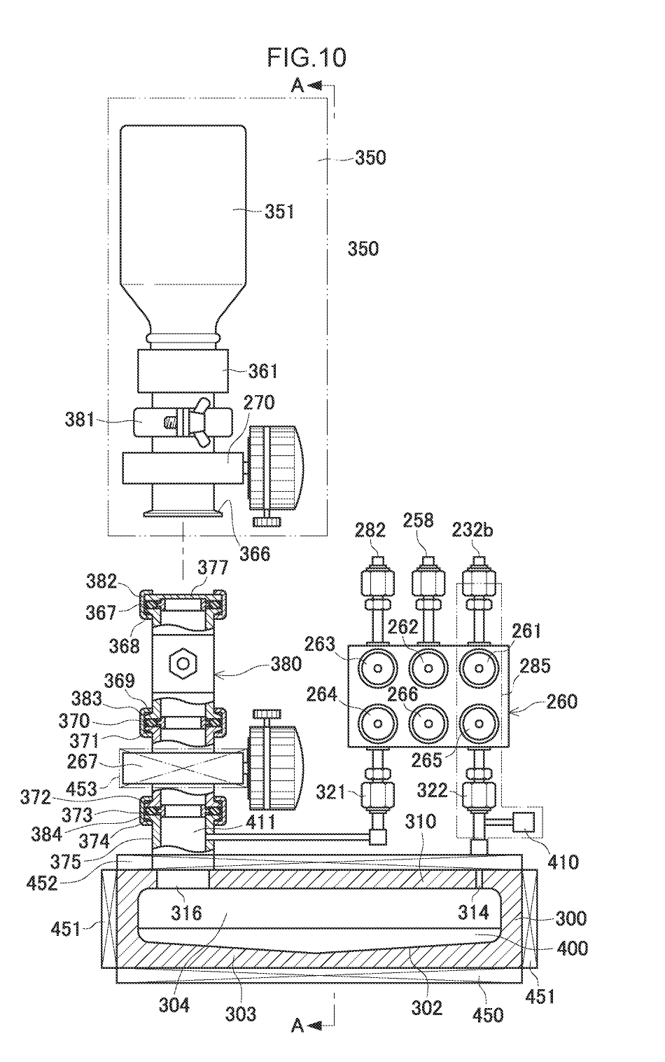

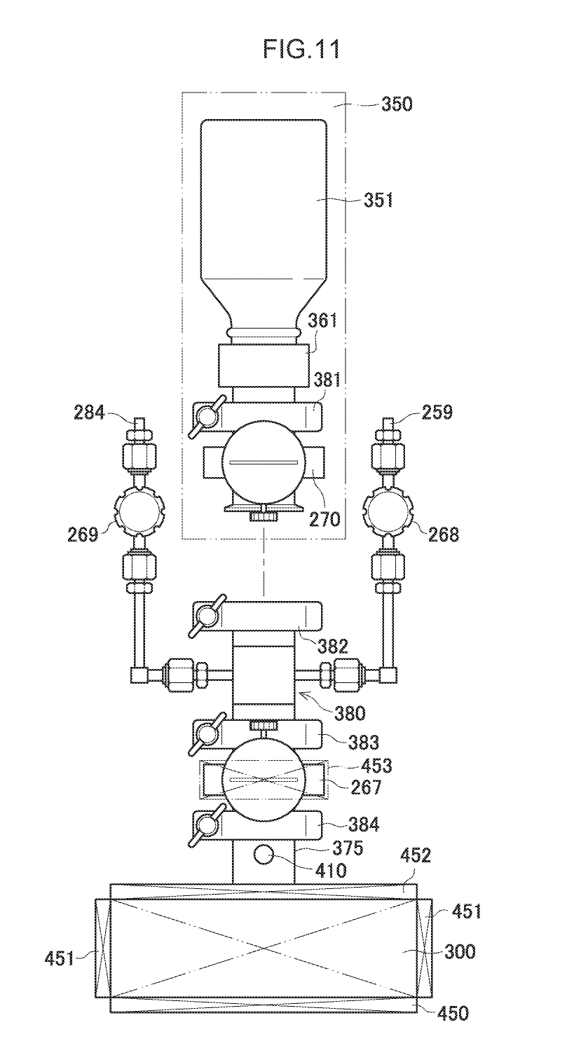

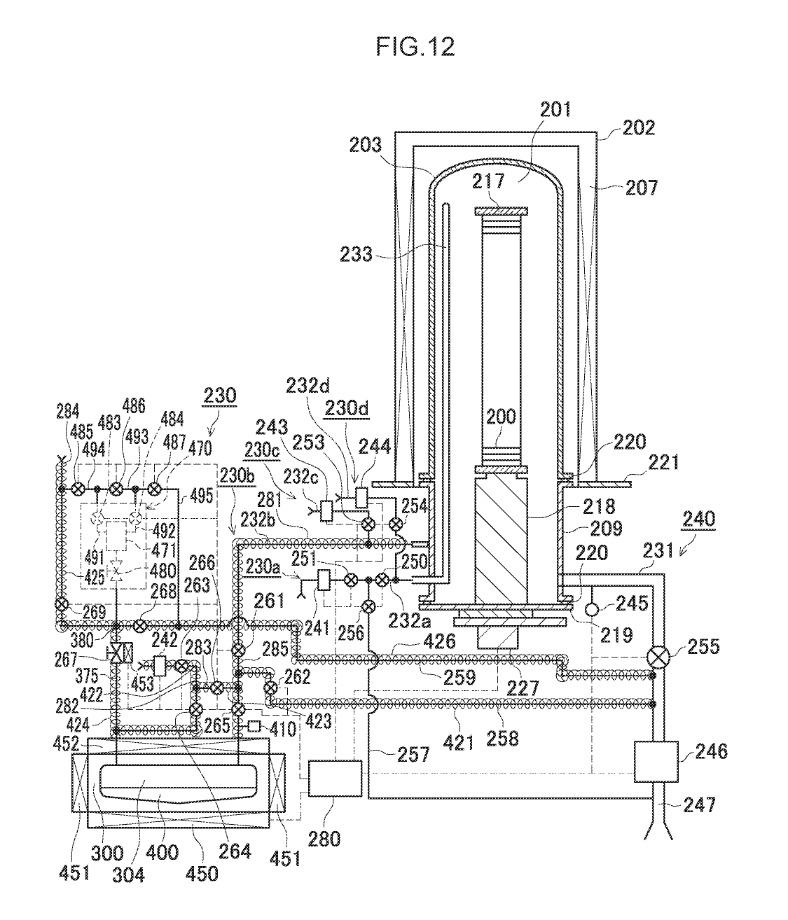

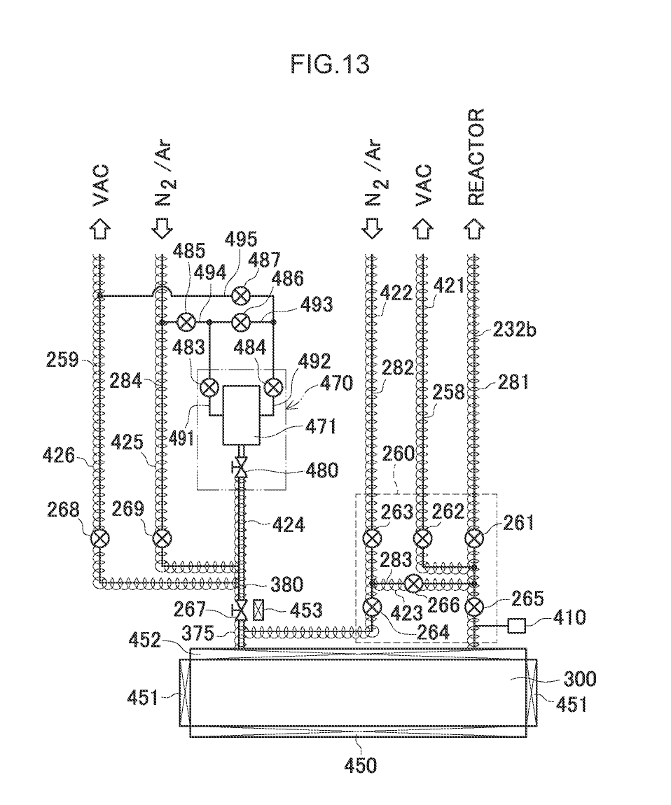

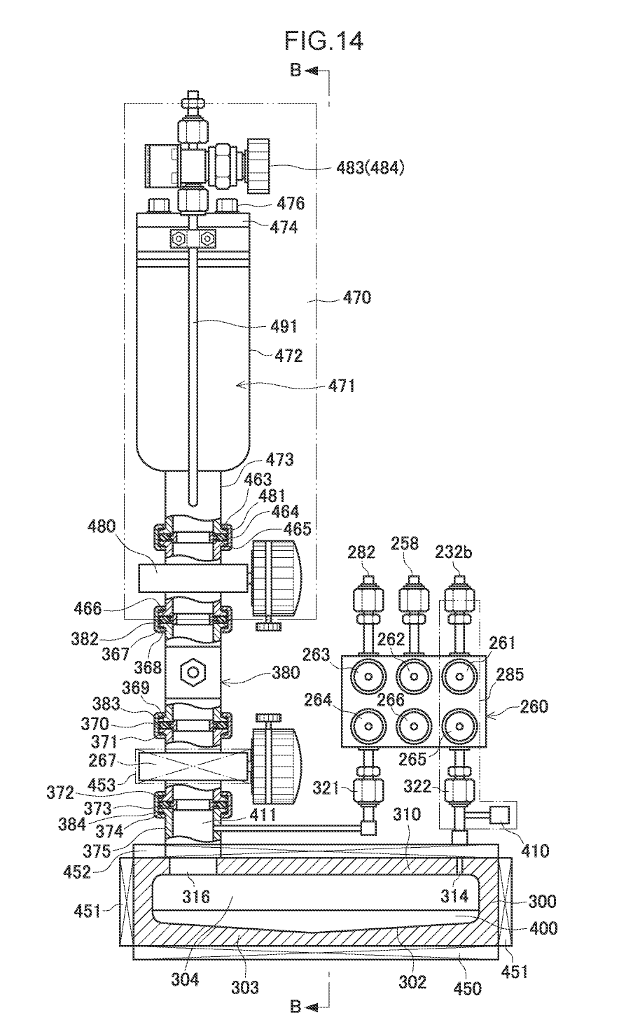

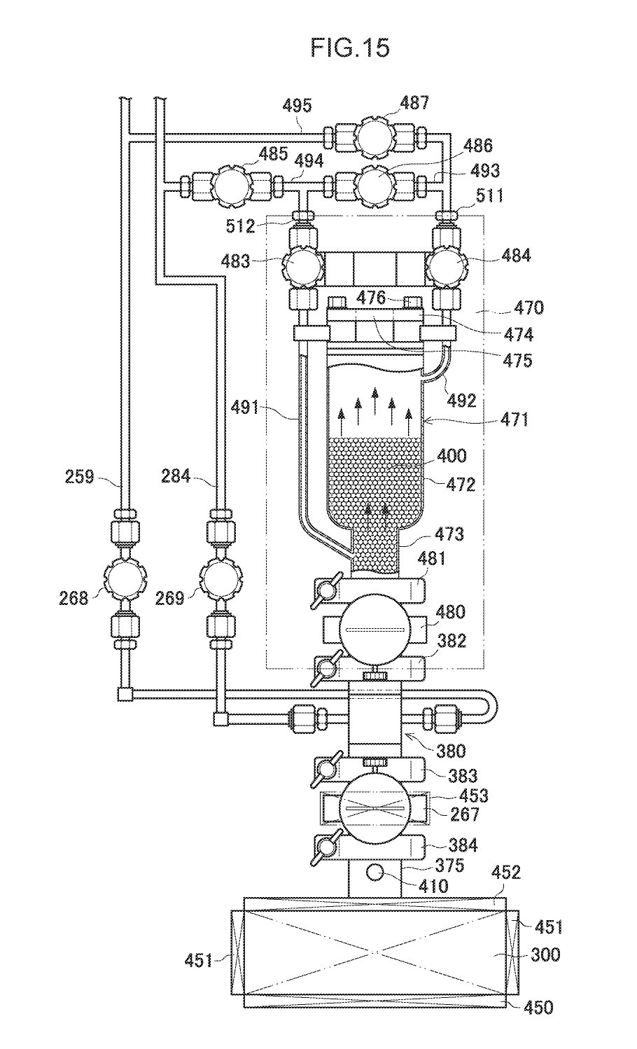

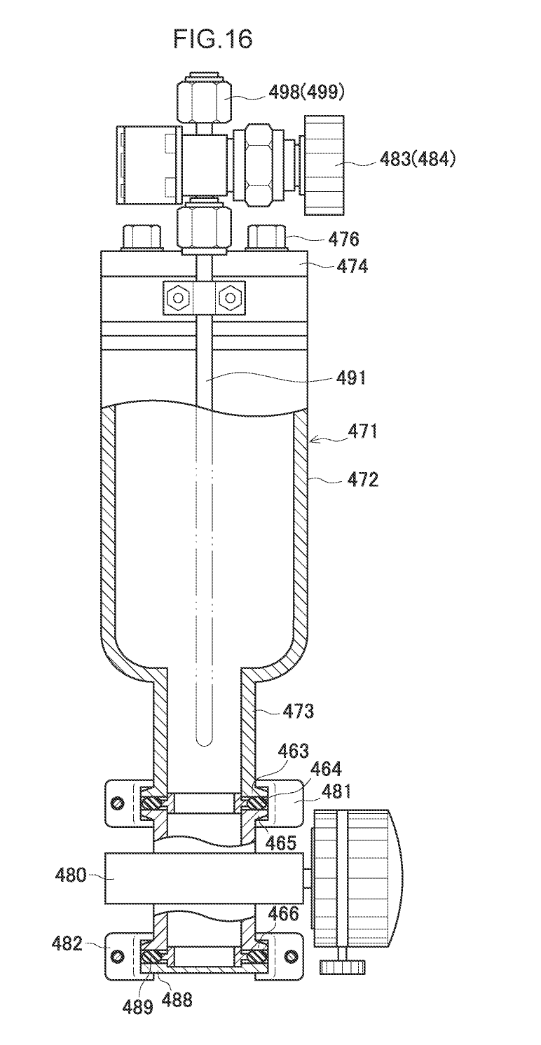

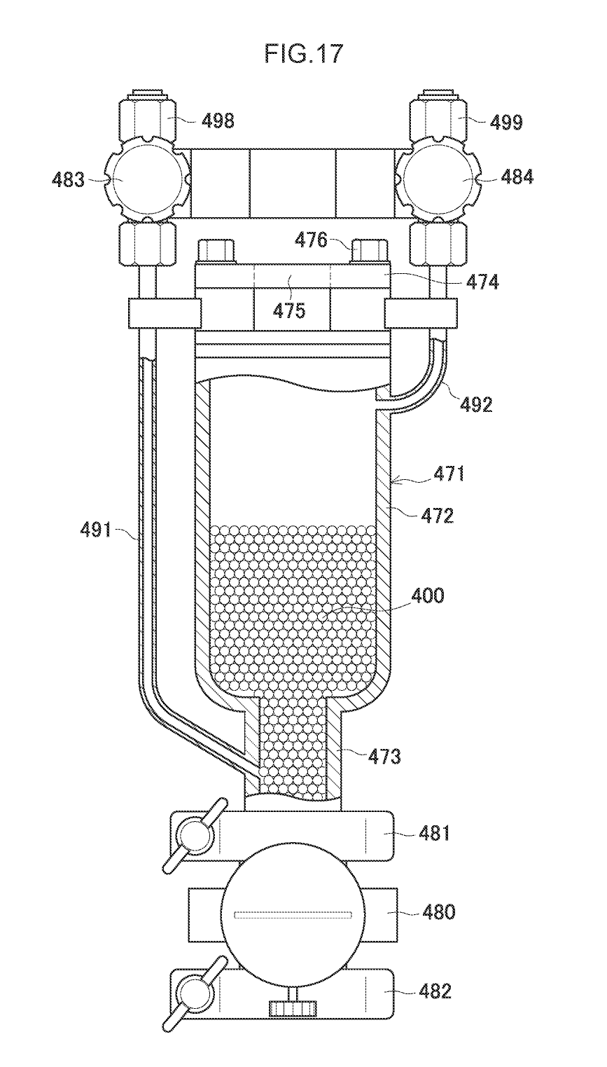

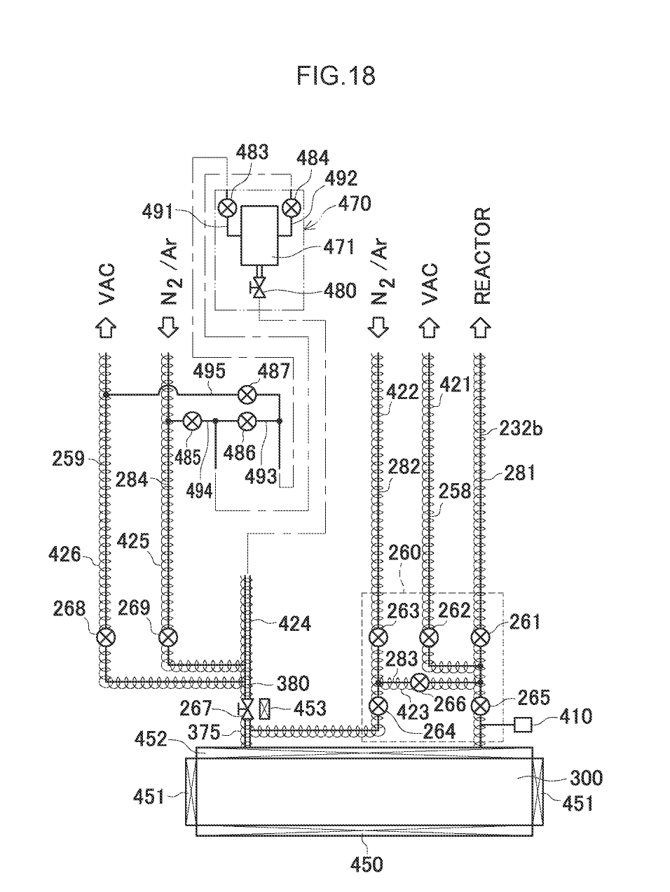

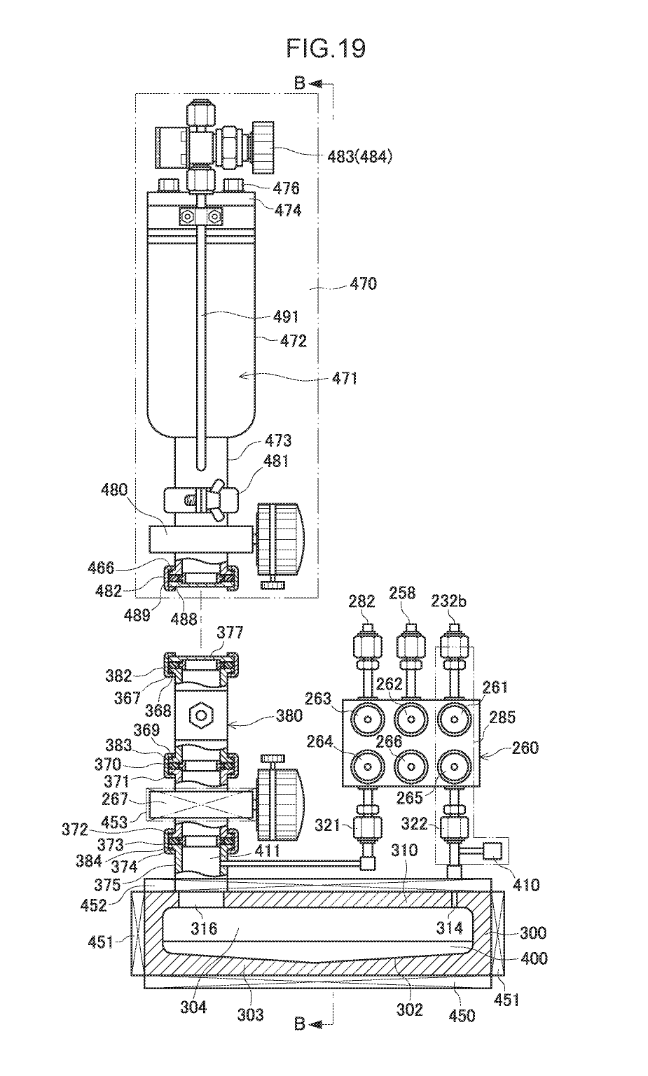

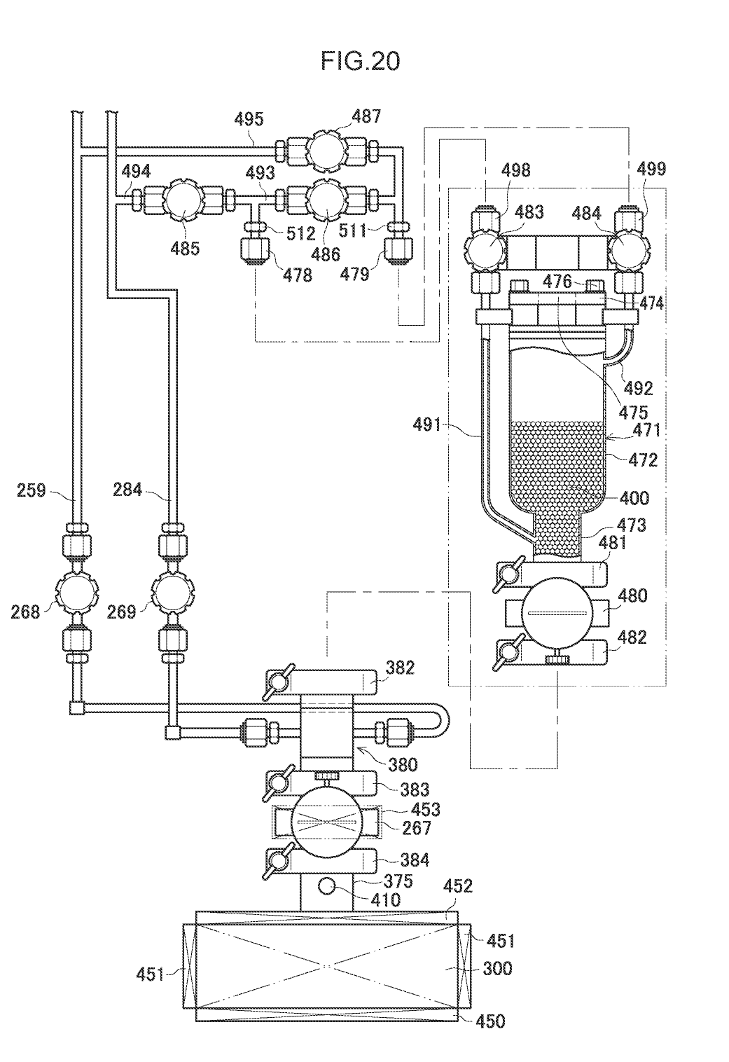

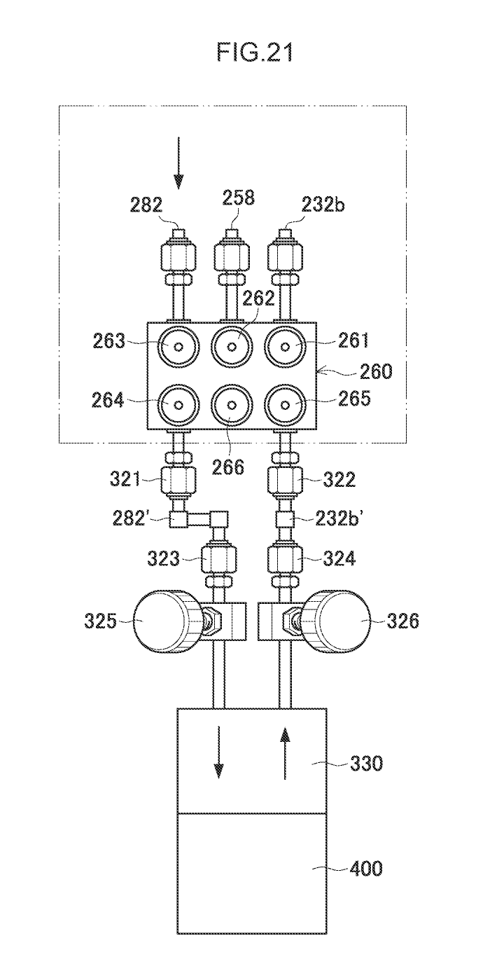

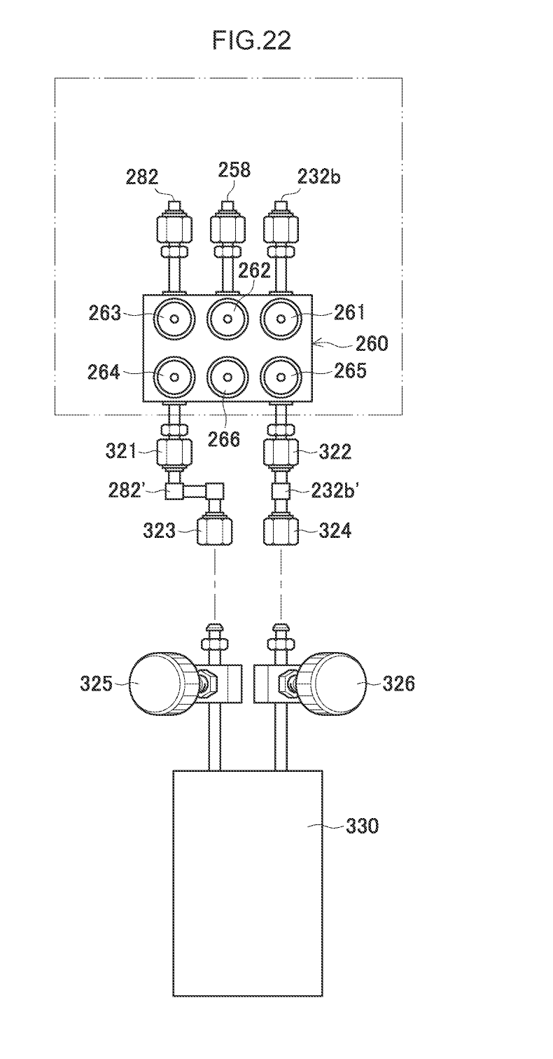

FIG. 5 is a schematic partial enlarged view of a portion A of FIG. 4;

FIG. 6 is a view for explaining a state when a raw material replenishing cartridge is attached to the substrate processing apparatus to be suitably used in the preferable first embodiment of the present invention, and piping or the like around a raw material supply tank and the raw material replenishing cartridge;

FIG. 7 is a partially cutaway schematic front view for explaining a state when the raw material replenishing cartridge is attached to the substrate processing apparatus to be suitably used in the preferable first embodiment of the present invention, and the piping or the like around the raw material supply tank and the raw material replenishing cartridge;

FIG. 8 is a schematic view, as seen from the direction of a line AA of FIG. 7, for explaining a state when the raw material replenishing cartridge is attached to the substrate processing apparatus to be suitably used in the preferable first embodiment of the present invention, and the piping or the like around the raw material supply tank and the raw material replenishing cartridge;

FIG. 9 is a schematic partial cross-sectional view for explaining the raw material replenishing cartridge to be suitably used in the preferable first embodiment of the present invention;

FIG. 10 is a partially cutaway schematic front view for explaining a state when the raw material replenishing cartridge is removed from the substrate processing apparatus to be suitably used in the preferable first embodiment of the present invention, and the piping or the like around the raw material supply tank and the raw material replenishing cartridge;

FIG. 11 is a schematic view, as seen from the direction of a line AA of FIG. 10, for explaining a state when the raw material replenishing cartridge is removed from the substrate processing apparatus to be suitably used in the preferable first embodiment of the present invention, and the piping or the like around the raw material supply tank and the raw material replenishing cartridge;

FIG. 12 is a schematic configuration view for explaining an example of a processing furnace of a substrate processing apparatus to be suitably used in a preferable second embodiment of the present invention, and a raw material supply system, an exhaust system, or the like that accompanies the processing furnace, and is a schematic configuration view showing a processing furnace portion in a schematic longitudinal section;

FIG. 13 is a view for explaining a state when the raw material replenishing cartridge is attached to the substrate processing apparatus to be suitably used in the preferable second embodiment of the present invention, and the piping or the like around the raw material supply tank and the raw material replenishing cartridge;

FIG. 14 is a partially cutaway schematic front view for explaining a state when the raw material replenishing cartridge is attached to the substrate processing apparatus to be suitably used in the preferable second embodiment of the present invention, and the piping or the like around the raw material supply tank and the raw material replenishing cartridge;

FIG. 15 is a schematic view, as seen from the direction of a line BB of FIG. 14, for explaining a state when the raw material replenishing cartridge is attached to the substrate processing apparatus to be suitably used in the preferable second embodiment of the present invention, and the piping or the like around the raw material supply tank and the raw material replenishing cartridge;

FIG. 16 is a schematic partial cross-sectional view for explaining the raw material replenishing cartridge to be suitably used in the preferable second embodiment of the present invention;

FIG. 17 is a schematic partial cross-sectional view for explaining the raw material replenishing cartridge to be suitably used in the preferable second embodiment of the present invention;

FIG. 18 is a view for explaining a state when the raw material replenishing cartridge is removed from the substrate processing apparatus to be suitably used in the preferable second embodiment of the present invention, and the piping or the like around the raw material supply tank and the raw material replenishing cartridge;

FIG. 19 is a partially cutaway schematic front view for explaining a state when the raw material replenishing cartridge is removed from the substrate processing apparatus to be suitably used in the preferable second embodiment of the present invention, and the piping or the like around the raw material supply tank and the raw material replenishing cartridge;

FIG. 20 is a schematic view, as seen from the direction of a line BB of FIG. 19, for explaining a state when the raw material replenishing cartridge is removed from the substrate processing apparatus to be suitably used in the preferable second embodiment of the present invention, and the piping or the like around the raw material supply tank and the raw material replenishing cartridge;

FIG. 21 is a view for explaining a technique of removing the raw material supply tank to replenish a solid raw material for comparison, and showing a state where the raw material supply tank is attached; and

FIG. 22 is a view for explaining the technique of removing the raw material supply tank to replenish a solid raw material for comparison, and showing a state where the raw material supply tank is removed.

### DETAILED DESCRIPTION OF THE INVENTION

Preferred embodiments of the present invention will be described below with reference to the drawings.

First, a substrate processing apparatus to be suitably used in preferable first and second embodiments of the present invention will be described. This substrate processing apparatus is configured as an example of a semiconductor manufacturing apparatus to be used for manufacture of a semiconductor device.

In the following description, a case where a vertical type apparatus that performs film formation processing or the like on substrates is used as an example of the substrate processing apparatus will be described. However, the invention is not based on the premise of the use of a vertical type apparatus, for example, a substrate by substrate processing apparatus may be used. Additionally, the present invention may be used not only for the film formation processing but for etching processing or the like.

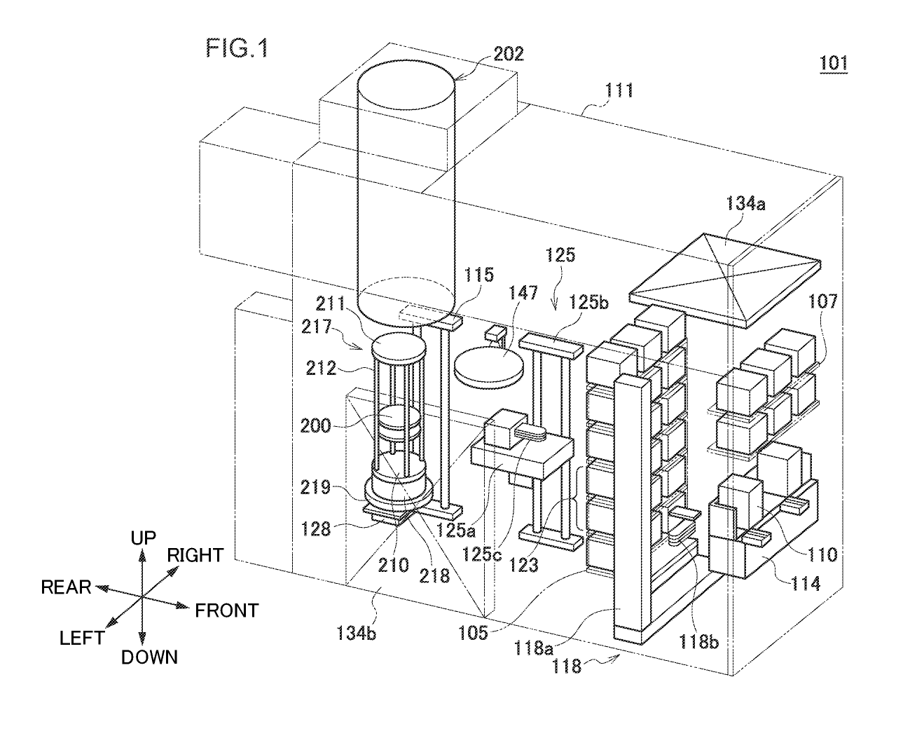

Referring to FIG. 1, in a substrate processing apparatus 101, a cassette 110 that houses wafers 200 that are examples of substrates is used, and the wafers 200 are made of materials, such as semiconductor silicon. The substrate processing apparatus 101 includes a housing 111, and a cassette stage 114 is installed inside the housing 111. The cassette 110 is carried in onto the cassette stage 114 by an intra-process conveying device (not shown), or is carried out from on the cassette stage 114.

The cassette 110 is placed on the cassette stage 114 by the intra-process conveying device (not shown) so that the wafers 200 within the cassette 110 hold a vertical posture and a wafer entrance of the cassette 110 is turned upward. The cassette stage 114 is configured so that the cassette 110 is rotated by 90° in a right-handed longitudinal direction rearward of the housing 111, the wafers 200 within the cassette 110 take a horizontal posture, and the wafer entrance of the cassette 110 becomes operable so to be directed to the back of the housing 111.

A cassette shelf 105 is installed substantially at a central portion in a front-and-rear direction within the housing 111, and plural stages of and plural rows of cassette shelves 105 are configured so as to keep plural cassettes 110. The cassette shelf 105 is provided with a transfer shelf 123 in which the cassette 110 that is a conveyance target of the wafer transfer mechanism 125 is housed.

A reserve cassette shelf 107 is provided above the cassette stage 114, and is configured so as to keep the cassette(s) 110 in reserve.

A cassette conveying device 118 is installed between the cassette stage 114 and the cassette shelf 105. The cassette conveying device 118 includes a cassette elevator 118a that can ascend and descend with the cassette 110 held, and a cassette conveying mechanism 118b serving as a conveying mechanism. The cassette conveying device 118 is configured so as to convey the cassette 110 between the cassette stage 114, the cassette shelf 105, and the reserve cassette shelf 107 by the interlocking operation between the cassette elevator 118a and the cassette conveying mechanism 118b.

A wafer transfer mechanism 125 is installed behind the cassette shelf 105. The wafer transfer mechanism 125 includes a wafer transfer device 125a that can rotate and linearly move the wafers 200 in the horizontal direction, and a wafer transfer device elevator 125b for elevating the wafer transfer device 125a. The wafer transfer device 125a is provided with tweezers 125c for picking up the wafers 200. The wafer transfer device 125 is configured so as to load (charge) the wafers 200 into a boat 217 and unload (discharge) the wafers 200 from the boat 217, using the tweezers 125c as a placing part, by the interlocking operation between the wafer transfer device 125a and the wafer transfer device elevator 125b.

A processing furnace 202 that heat-treats the wafers 200 is provided above a rear part of the housing 111, and the processing furnace 202 is configured so that the lower end thereof is opened and closed by a furnace port shutter 147.

A boat elevator 115 that elevates the boat 217 with respect to the processing furnace 202 is provided below the processing furnace 202. An arm 128 is coupled with an elevating platform of the boat elevator 115, and a seal cap 219 is horizontally installed at the arm 128. The seal cap 219 is configured so as to be able to vertically support the boat 217 and block the lower end of the processing furnace 202.

The boat 217 includes plural holding members, and is configured as to horizontally support plural wafers (for example, about 50 to 150 sheets) 200 in a state where the wafers are aligned in the vertical direction with their centers arranged.

A cleaning unit 134a that supplies clean air that is a cleaned atmosphere is installed above the cassette shelf 105. The cleaning unit 134a includes a supply fan (not shown) and a dustproof filter (not shown), and is configured so as to circulate clean air through the inside of the housing 111.

A cleaning unit 134b that supplies clean air is installed at a left end of the housing 111. The cleaning unit 134b also includes a supply fan (not shown) and a dustproof filter (not shown), and is configured so as to circulate clean air through the vicinity of the wafer transfer device 125a, boat 217, or the like. After the clean air is circulated through the vicinity of wafer transfer device 125a, boat 217, or the like, the air is exhausted to the outside of the housing 111.

Next, the main operation of the substrate processing apparatus 101 will be described.

When the cassette 110 is carried in onto the cassette stage 114 by the intra-process conveying device (not shown), the cassette 110 is placed on the cassette stage 114 so that the wafers 200 hold a vertical posture on the cassette stage 114 and the wafer entrance of the cassette 110 is turned upward. Thereafter, the cassette 110 is rotated by 90° in a right-handed longitudinal direction rearward of the housing 111 so that the wafers 200 within the cassette 110 take a horizontal posture by the cassette stage 114 and the wafer entrance of the cassette 110 is directed to the back of the housing 111.

Thereafter, the cassette 110 is automatically conveyed and transferred to a shelf position specified by the cassette shelf 105 or the reserve cassette shelf 107, by the cassette conveying device 118, and is temporarily kept. Then, the cassette is transferred to the transfer shelf 123 by the cassette conveying device 118 from the cassette shelf 105 or the reserve cassette shelf 107, or is directly conveyed to the transfer shelf 123.

If the cassette 110 is transferred to the transfer shelf 123, the wafers 200 are picked up through a wafer entrance of the cassette 110 by the tweezers 125c of the wafer transfer device 125a from the cassette 110, and are loaded (charged) into the boat 217. The wafer transfer device 125a that has transferred the wafers 200 to the boat 217 returns to the cassette 110, and loads the boat 217 with the subsequent wafers 200.

If the boat 217 is loaded with previously specified sheets of wafers 200, the furnace port shutter 147 that has closed the lower end of the processing furnace 202 is opened, and the lower end of the processing furnace 202 is opened. Thereafter the boat 217 holding the wafers 200 group is carried (loaded) into the processing furnace 202 by an ascending operation of the boat elevator 115, and a lower part of the processing furnace 202 is blocked by the seal cap 219.

After the loading, arbitrary processing is carried out on the wafers 200 in the processing furnace 202. After the processing, the cassette 110 and the wafers 200 are carried out to the outside of the housing 111 according to a reverse procedure to the above-described procedure.

### First Embodiment

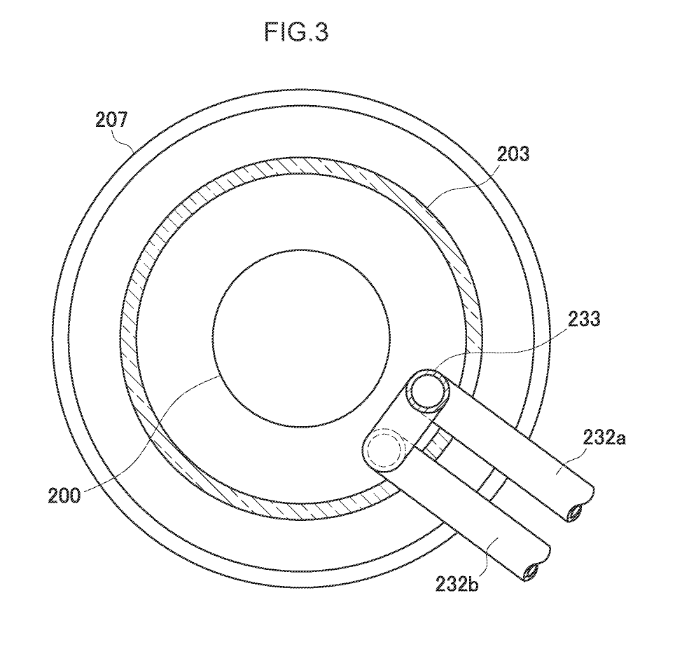

Next, the processing furnace 202, the raw material supply system 230, the exhaust system 240, and the like of the first embodiment to be used for the substrate processing apparatus 101 mentioned above with reference to FIGS. 2 to 5 will be described.

Referring to FIG. 2, the processing furnace 202 is provided with a heater 207 that is a heating device (heating means) for heating the wafers 200. The heater 207 includes a cylindrical heat-insulating member of which the upside is blocked, and plural heater wires, and has a unit configuration in that the heater element wires are provided with respect to the heat-insulating member. A reaction tube 203 made of quartz for processing the wafers 200 is provided inside the heater 207.

A manifold 209 is provided at a lower part of the reaction tube 203. The manifold 209 is fixed to a heater base 221 serving as a holding member. Annular flanges are respectively provided at a lower end of the reaction tube 203 and an upper opening end of the manifold 209, and an airtight member (hereinafter referred to as an O ring) 220 is arranged between these flanges to airtightly seal a gap between both of them.

A seal cap 219 serving as a furnace port lid body that can airtightly block a lower end opening of the manifold 209 is provided below the manifold 209. The seal cap 219 is adapted to abut on a lower end of the manifold 209 from the vertical downside. The seal cap 219 is made of metals, such as stainless steel, and is formed in the shape of a disk. The airtight member (hereinafter referred to as an O ring) 220 is arranged between the annular flange provided at the lower opening end of the manifold 209 and the top face of a seal cap 219 to airtightly seal a gap between both of them. A processing chamber 201 is formed by at least the reaction tube 203, the manifold 209, and the seal cap 219.

The seal cap 219 is provided with a boat support 218 that supports the boat 217. The boat 217 has a bottom plate 210 fixed to the boat support 218, and a top plate 211 arranged above the bottom plate, and has a configuration in which plural struts 212 are laid between the bottom plate 210 and the top plate 211 (refer to FIG. 1). Plural wafers 200 are held by the boat 217. The plural wafers 200 are loaded in multiple stages in the tube axis direction of the reaction tube 203 and supported by the struts 212 of the boat 217, in a state where the horizontal posture is held at certain intervals from each other.

A rotating mechanism 227 that rotates the boat is provided on the side of the seal cap 219 opposite to the processing chamber 201. The rotating mechanism 227 is connected to the boat support 218 through the seal cap 219, and the boat 217 is rotated via the boat support 218 by the rotating mechanism 227 to rotate the wafers 200.

The seal cap 219 is elevated in the vertical direction by the boat elevator 115 serving as an elevating mechanism provided outside the reaction tube 203, and thereby, the boat 217 is enabled to be carried in and carried out with respect to the inside of the processing chamber 201.

In the above processing furnace 202, the boat 217 is inserted into the processing chamber 201 while being supported by the boat support 218, in a state where the plural wafers 200 are loaded onto the boat 217. The plural wafers 200 to be subjected to batch processing are loaded in multiple stages in the tube axis direction of the reaction tube 203 in the horizontal posture, on the boat 217 inserted into the processing chamber 201. The heater 207 is adapted to heat the wafers 200 inserted into the processing chamber 201 to a predetermined temperature.

Referring to FIGS. 2 to 5, two gas supply pipes 232a and 232b as supply paths that supply plural kinds of gas, here two kinds of gas to the processing chamber 201 are provided. The ends of the gas supply pipes 232a and 232b are provided so as to pass through a lower part of the manifold 209, the gas supply pipe 232b joins the gas supply pipe 232a within the processing chamber 201, and the two gas supply pipes 232a and 232b communicate with the lower end of one multihole nozzle 233. As shown in FIG. 5, plural gas supply holes 238b that emit gas is provided in an upper part of the nozzle 233.

The nozzle 233 is provided almost vertically within the processing chamber 201, and is disposed along the loading direction of the wafers 200 from an upper part of the reaction tube 203 to a lower part thereof. The upper part of the reaction tube 203 is arranged so as to extend to a region having a temperature equal to or higher than the decomposition temperature of a source gas with that is supplied from the gas supply pipe 232b. On the other hand, a part where the gas supply pipe 232b joins the gas supply pipe 232a within the processing chamber 201 is a region having a temperature lower than the decomposition temperature of the source gas, and a region having a temperature lower than the temperature the wafers 200 and near the wafers.

A mass flow controller 241 serving as flow rate control means and valves 251 and 250 that are opening and closing valves are provided in the gas supply pipe 232a sequentially from the upstream. Moreover, a vent line 257 and a valve 256 that are connected to an exhaust pipe 247 to be described below are provided between the valve 250 and the valve 251 in the gas supply pipe 232a.

A gas supply system 230a is mainly constituted by the gas supply pipe 232a, the massflow controller 241, the valves 250 and 251, the nozzle 233, the vent line 257, and the valve 256.

Additionally, a carrier gas supply pipe 232d for supplying carrier gas is connected to the gas supply pipe 232a on the downstream side of the valve 250. The carrier gas supply pipe 232d is provided with a mass flow controller 244 and a valve 254. A carrier gas supply system 230d (inert gas supply system) is mainly constituted by the carrier gas supply pipe 232d, the mass flow controller 244, and the valve 254. For example, nitrogen (N₂) gas or argon (Ar) gas is supplied from the carrier gas supply system 230d.

In the gas supply pipe 232a, a gaseous source gas, of which the flow rate is adjusted by the mass flow controller 241, is supplied. In addition, while the source gas is not supplied to the processing chamber 201, the valve 250 is closed, the valve 256 is opened, and the source gas is made to flow to the vent line 257 via the valve 256.

Then, when the source gas is supplied to the processing chamber 201, the valve 256 is closed, the valve 250 is opened, and the source gas is supplied to the gas supply pipe 232a on the downstream side of the valve 250. On the other hand, the carrier gas, of which the flow rate is adjusted by the mass flow controller 244, is supplied from the carrier gas supply pipe 232d via the valve 254, and the source gas joins the carrier gas on the downstream side of the valve 250, and is supplied to the processing chamber 201 via the nozzle 233.

In the present embodiment, for example, ammonia gas (NH₃) serving as the source gas is supplied to the gas supply pipe 232a, and is supplied to the processing chamber 201 via the nozzle 233. The reason why the ammonia gas is supplied is because a case where a GaN film is formed is assumed. An ozone gas, H₂O, H₂+CO₂ gas, or the like is suitably supplied instead of ammonia gas according to the type of films to be formed.

A solid raw material tank 300 that stores a solid raw material 400 is connected to an upstream end of the gas supply pipe 232b. Valves 265 and 261 that are opening and closing valves are provided in the gas supply pipe 232b sequentially from the solid raw material tank 300. Moreover, a vent line 258 and a valve 262 that are connected to an exhaust pipe 231 to be described below are provided between the valve 265 and the valve 261 in the gas supply line 232b. The gas supply pipe 282 is connected to the solid raw material tank 300 via piping 375. A mass flow controller 242 serving as flow rate control means and valves 263 and 264 that are opening and closing valves are provided in the gas supply pipe 282 sequentially from the upstream. Piping 283 is connected between the gas supply pipe 232b between a valve 265 and the valve 261 and the gas supply pipe 282 between a valve 263 and a valve 264. The piping 283 is provided with a valve 266 that is an opening and closing valve. The valves 261 to 266, a portion of the gas supply pipe 282, a portion of the gas supply pipe 232b, and the piping 283 are constituted as a set valve 260, as shown in FIGS. 7 and 8.

Heaters 450, 451, and 452 that heat the solid raw material tank 300 are provided. The bottom face, lateral face, and ceiling portion of the solid raw material tank 300, are heated by the heaters 450, 451, and 452, respectively, the stored solid raw material 400 of the solid raw material tank 300 is heated to a predetermined temperature, and adhesion of the raw material to the inner wall of the solid raw material tank 300 by re-solidification is prevented. Additionally, since a heater 281 is wound around the gas supply pipe 232b from the valve 261 to the manifold 209, a heater 285 is wound around the gas supply pipe 232b from the solid raw material tank 300 to the valve 261, and a heater 421 is wound around the vent line 258 so that heating is enabled in order to prevent adhesion of the raw material to the inner walls of the pipes by re-solidification. Moreover, a heater 453 is also wound around the valve 267 to be described below so that heating is enabled in order to prevent adhesion of the raw material to the inner wall of the valve by re-solidification.

Additionally, a pressure sensor 410 is provided at the gas supply pipe 232b between the valve 265 and the solid raw material tank 300. The pressure sensor 410 is able to cope with heating and high temperature. The pressure sensor 410 monitors the partial pressure within the solid raw material tank 300 and observes whether or not the raw material sublimates in the solid raw material tank 300 and is in a proper pressure state or whether or not the residual quantity of the raw material decreases and the pressure drops.

A gas supply system 230b is mainly constituted by the gas supply pipe 282, the massflow controller 242, the valves 263 and 264, the piping 375, the solid raw material tank 300, the gas supply pipe 232b, the valves 265 and 261, the nozzle 233, the vent line 258, and the valve 262.

Additionally, a carrier gas supply pipe 232c for supplying carrier gas is connected to the gas supply pipe 232b on the downstream side of the valve 261. The carrier gas supply pipe 232c is provided with a mass flow controller 243 and a valve 253. A carrier gas supply system 230c (inert gas supply system) is mainly constituted by the carrier gas supply pipe 232c, the mass flow controller 243, and the valve 253. For example, nitrogen (N₂) gas or argon (Ar) gas is supplied from the carrier gas supply system 230c.

If the solid raw material tank 300 that stores the solid raw material 400 is heated to a predetermined temperature by the heaters 450, 451, and 452, the solid raw material 400 sublimates, turns into a gas, and is present in the space 304 within the solid raw material tank 300 with a predetermined partial pressure corresponding to the predetermined temperature. In that state, for example, nitrogen (N₂) gas serving as the carrier gas, of which the flow rate is adjusted by the massflow controller 242, is supplied to the piping 282. The nitrogen (N₂) gas is supplied to the space 304 within the solid raw material tank 300 via the valves 263 and 264 and the piping 375, and the solid raw material 400 turned into a gas flows into the piping 232b along with the nitrogen (N₂) gas. In addition, while the solid source gas 400 turned into a gas is not supplied to the processing chamber 201, the valve 261 is closed, the valve 262 is opened, and the source gas is made to flow to the vent line 262 via the valve 258.

Then, when the solid raw material 400 turned into a gas is supplied to the processing chamber 201, the valve 262 is closed, the valve 261 is opened, and the solid raw material 400 turned into a gas is supplied to the gas supply pipe 232b on the downstream side of the valve 261 along with the nitrogen (N₂) gas. On the other hand, the nitrogen (N₂) gas that is the carrier gas, of which the flow rate is adjusted by the mass flow controller 243, is supplied from the carrier gas supply pipe 232c via the valve 253, and the solid raw material 400 turned into a gas and the nitrogen (N₂) gas join the carrier gas (nitrogen gas) supplied from the carrier gas supply pipe 232c on the downstream side of the valve 261, and are supplied to the processing chamber 201 via the nozzle 233.

In the present embodiment, for example, GaCl₃ is used as the solid raw material 400, and GaCl₃ that has sublimated and turned into a gas is supplied to the gas supply pipe 232b and is supplied to the processing chamber 201 via the nozzle 233. The reason why GaCl₃ is used as the solid raw material 400 is because a case where a GaN film is formed is assumed, and AlCl₃ or the like is suitably used instead of GaCl₃ according to the type of films to be formed.

The raw material supply system 230 is mainly constituted by the gas supply system 230a, the gas supply system 230b, the carrier gas supply system 230c, and the carrier gas supply system 230d.

In addition, the piping 283 and the valve 266 are used for purging and are normally closed. When purging is performed, the valves 264 and 265 are closed, the valves 263 and 266 are opened, the valve 261 or 262 is opened, and purging is performed via the gas supply pipe 282, the valve 263, the piping 283, the valve 266, the gas supply pipe 232b, and the valve 261, or via the gas supply pipe 282, the valve 263, the piping 283, the valve 266, the vent line 258, and the valve 262.

The exhaust pipe 231 that exhausts the atmosphere within the processing chamber 201 is connected to the manifold 209. A vacuum pump 246 as an evacuation apparatus is connected to the exhaust pipe 231 via a pressure sensor 245 serving as a pressure sensor (pressure detecting unit) that detects the pressure within the processing chamber 201 and an APC (Auto Pressure Controller) valve 255 serving as a pressure adjustor (pressure adjusting unit), and is configured so that the pressure within the processing chamber 201 becomes a predetermined pressure (degree of vacuum) and evacuation can be made. The exhaust pipe 247 on the downstream side of the vacuum pump 246 is connected to a waste gas processing apparatus (not shown) or the like. In addition, the APC valve 255 is an opening and closing valve that can be opened and closed to perform the evacuation and evacuation stop within the processing chamber 201 and that can adjust the valve opening degree to adjust conductance to perform pressure adjustment within the processing chamber 201. The exhaust system 240 is mainly constituted by the exhaust pipe 231, the APC valve 255, the vacuum pump 246, and the pressure sensor 245.

A temperature sensor (not shown) serving as a temperature detector is installed within the reaction tube 203, and is configured so that the temperature within the processing chamber 201 has a desired temperature distribution by adjusting a supply voltage to the heater 207 on the basis of temperature information detected by the temperature sensor.

The boat 217 is provided at a central portion within the reaction tube 203. The boat 217 can be elevated (moved in and out) with respect to the reaction tube 203 by the boat elevator 115 (refer to FIG. 1). If the boat 217 is introduced into the reaction tube 203, the lower end of the manifold 209 is airtightly sealed with the seal cap 219 via an O ring 220. The boat 217 is supported by the boat support 218. In order to improve the uniformity of processing, the boat rotating mechanism 227 is driven to rotate the boat 217 supported by the boat support 218.

The respective members, such as the above-described mass flow controllers 241, 242, 243, and 244, valves 250, 251, 253, 254, 256, 261, 262, 263, 264, 265, 266, 268, and 269, APC valve 255, heaters 207, 281, 285, 421, 450, 451, and 452, temperature sensor (not shown), pressure sensor 245, vacuum pump 246, boat rotating mechanism 227, and boat elevator 115, and the valves 268 and 269 to be described below, are connected to the controller 280. The controller 280 is an example of a control unit (control means) that controls the overall operation of the substrate processing apparatus 101, and is adapted to control the flow rate adjustment of the mass flow controllers 241, 242, 243, and 244, the opening and closing operation of the valves 250, 251, 253, 254, 256, 261, 262, 263, 264, 265, and 266 and valves 268 and 269, a pressure adjustment operation based on the opening and closing of the APC valve 255 and the pressure sensor 245, the temperature adjustment operation of the heaters 281, 285, 421, 450, 451, and 452, the temperature adjustment operation of the heater 207 based on a temperature sensor (not shown), the start or stop of the vacuum pump 246, the rotating-speed regulation of the boat rotating mechanism 227, the elevation operation of a boat elevator 115, or the like, respectively. In addition, the valves 250, 251, 253, 254, 256, 261, 262, 263, 264, 265, 266, 268, and 269 are air valves, and are controlled by the controller 280 via electromagnetic valves, respectively.

Next, the process of forming a GaN film using the above-described substrate processing apparatus 101 will be described. In addition, the following steps are performed by the control of the controller 280.

The heater 207 is controlled to hold the inside of the processing chamber 201 at a predetermined temperature.

Thereafter, if the boat 217 is loaded with plural wafers 200, the boat 217 that supports the plural wafers 200 is lifted by the boat elevator 115 and is carried into the processing chamber 201. In this state, the seal cap 219 is brought into a state where the lower end of the manifold 209 is sealed via the O ring 220.

Thereafter, the boat 217 is rotated by the boat rotating mechanism 227 to rotate the wafers 200. Thereafter, if the APC valve 255 is opened, the inside of the processing chamber 201 is vacuumed by the vacuum pump 246, and the temperature or the like of the wafers 200 is stabilized, the following steps are sequentially executed.

In the present embodiment, a GaN film is formed using an ALD (Atomic Layer Deposition) method. The ALD method is the technique of alternately supplying source gases that become at least two types of raw materials used for film formation to a substrate one by one under certain film forming conditions (temperature or the like), making the source gases adsorbed on the substrate in units of one atom, and forming a film using a surface reaction. At this time, the control of film thickness is performed with the number of cycles in which the source gases are supplied (for example, if the deposition rate is set 1 Å/cycle, formation of a 20 Å film is performed in 20 cycles).

The solid raw material tank 300 that stores powder-processed GaCl₃ as the solid raw material 400 is heated to a predetermined temperature by the heaters 450, 451, and 452. Additionally, the gas supply pipe 232b is heated to a predetermined temperature by the heaters 281 and 285, and the vent line 258 is heated to a predetermined temperature by the heater 421.

The APC valve 255 of the exhaust pipe 231 is opened at a predetermined angle, the valves 263, 264, and 265 are opened to supply nitrogen (N₂) to the solid raw material tank 300 from the piping 282 as the carrier gas, and the valve 261 is opened to supply GaCl₃ turned into a gas to the gas supply pipe 232b along with the nitrogen gas. Additionally, the valve 253 is opened to supply the nitrogen (N₂) gas that is the carrier gas from the carrier gas supply pipe 232c, and GaCl₃ turned into a gas and the nitrogen gas are made to join the nitrogen gas supplied from the carrier gas supply pipe 232c on the downstream side of the valve 261 and are supplied to the processing chamber 201 via the nozzle 233.

Next, the valve 261 and the valve 253 are closed to stop the supply of GaCl₃ turned into a gas and the nitrogen gas to the processing chamber 201, and the inside of the processing chamber 201 is exhausted by the vacuum pump 246 with the APC valve 255 of the exhaust pipe 231 being opened, and remaining GaCl₃ is removed from the inside of the processing chamber 201.

With the APC valve 255 of the exhaust pipe 231 being opened at a predetermined angle, the valves 251 and 250 are opened to supply NH₃ gas to the gas supply pipe 232a. Additionally, the valve 254 is opened to supply the nitrogen gas that is the carrier gas from the carrier gas supply pipe 232d, and NH₃ gas is made to join the nitrogen gas supplied from the carrier gas supply pipe 232d on the downstream side of the valve 251, and is supplied to the processing chamber 201 via the nozzle 233.

Next, the valve 250 and the valve 254 are closed to stop the supply of the NH₃ gas and the nitrogen gas to the processing chamber 201, and the inside of the processing chamber 201 is exhausted by the vacuum pump 246 with the APC valve 255 of the exhaust pipe 231 being opened, and remaining NH₃ is removed from the inside of the processing chamber 201.

The above four processes including the supply of GaCl₃ turned into a gas to the processing chamber 201, the removal of GaCl₃ from the processing chamber 201, the supply of the NH₃ gas to the processing chamber 201, and the removal of the NH₃ gas from the processing chamber 201 is defined as one cycle, and a GaN film is formed on the wafers 200 by repeating these processes by a predetermined number of times.

If the film formation processing of forming a GaN film with a predetermined film thickness is made, the inside of the processing chamber 201 is purged with an inert gas such as N₂ by exhausting the inert gas while supplying the inert gas into the processing chamber 201. Thereafter, the atmosphere in the processing chamber 201 is replaced with the inert gas, and the pressure within the processing chamber 201 is returned to atmospheric pressure. Thereafter, the seal cap 219 is lowered by the boat elevator 115, the opening of the lower end of the manifold 209 is opened, and processed wafers 200 are carried out to the outside of the processing chamber 201 from the lower end of the manifold 209 in a state where the wafers are loaded on the boat 217. Thereafter, the processed wafers 200 are taken out from the boat 217.

If the film formation of the GaN film to the wafers 200 is repeated as described above and the solid raw material tank 300 becomes empty, replenishment of the solid raw material tank 300 is performed on the solid raw material 400.

Next, the structure and replenishing method for replenishing the solid raw material tank 300 with the solid raw material 400 will be described.

Referring to FIGS. 2 and 6 to 8, the solid raw material tank 300 has a sealed structure. A bottom 303 of the solid raw material tank 300 is provided with an inclination portion 302 with a low center and a high peripheral portion. Through holes 314 and 316 are provided in a ceiling plate 310 of the solid raw material tank 300. The valve 265 of the gas supply pipe 232b is connected to the through hole 314 via a joint 322. The piping 375 is connected to the through hole 316. The valve 267 is connected to the piping 375, piping 380 is connected to the valve 267, and a raw material replenishing cartridge 350 for replenishing the solid raw material 400 is attached to the piping 380. Additionally, the valve 264 of the gas supply pipe 282 is connected to the piping 375 via a joint 321.

A flange 372 of the valve 267 is fixed to a flange 374 of the piping 375 by a clamp 384 via an O ring 373. A flange 369 of the piping 380 is fixed to a flange 371 of the valve 267 by a clamp 383 via an O ring 370. A flange 366 of the valve 270 of the raw material replenishing cartridge 350 is fixed to a flange 368 of the piping 380 by a clamp 382 via an O ring 367. The flange 368 of the piping 380 is located right above the through hole 316. The valve 267 and the valve 270 are manual valves.

Purge gas supply piping 284 and piping 259 are connected to the piping 380. The purge gas supply piping 284 is provided with the valve 269. As a purge gas to be supplied to the purge gas supply piping 284, for example, nitrogen (N₂) gas is used. The piping 259 is connected to the exhaust pipe 231 on the downstream side of the vacuum pump 246 (refer to FIG. 2). The piping 259 is provided with a valve 268. The opening and closing operation of the valves 268 and 269 is controlled by the controller 280.

In addition, the above-described raw material supply system 230 includes not only the gas supply system 230a, the gas supply system 230b, the carrier gas supply system 230c, and the carrier gas supply system 230d but also the purge gas supply piping 284, the piping 259, and the valves 268 and 269 that are connected to the solid raw material tank 300.

Referring to FIG. 9, the raw material replenishing cartridge 350 includes a bottle 351, a valve 270, and an adapter 360, and the valve 270 is attached to the bottle 351 via the adapter 360. An outer peripheral portion of a mouth 353 of a bottle 351 is provided with a groove 355. An inner peripheral portion of one end 361 of the adapter 360 is provided with a groove 362. Packing 357 made of PTFE is provided between the mouth 353 of the bottle 351 and the adapter 360, and the adapter 360 is attached to the mouth 353 of the bottle 351 via the packing 357. The other end of the adapter 360 is provided with a flange 363. A flange 365 of the valve 270 is fixed to the flange 363 of the adapter 360 by a clamp 381 via an O ring 364.

FIGS. 7 and 8 show a state where the raw material replenishing cartridge 350 is attached to the piping 380, and FIGS. 10 and 11 show a state where the raw material replenishing cartridge 350 is removed from the piping 380. Referring to FIG. 10, after the raw material replenishing cartridge 350 is removed from the piping 380, a closing plate 377 is fixed to the flange 368 of the piping 380 by the clamp 382 via the O ring 367.

Next, a method of replenishing the solid raw material tank 300 with the solid raw material 400 using the raw material replenishing cartridge 350 will be described.

If the solid raw material tank 300 becomes empty, the raw material replenishing cartridge 350 is attached to the piping 380. In this case, the flange 366 of the valve 270 of the raw material replenishing cartridge 350 is fixed to the flange 368 of the piping 380 by the clamp 382 via the O ring 367. In addition, the valves 267 and 270 remain closed. After the raw material replenishing cartridge 350 is attached to the piping 380, the valve 268 is opened, and the inside of the piping 380 is vacuumed by the vacuum pump 246 via the piping 259 and the exhaust pipe 231. Thereafter, the valve 268 is closed and the valve 269 is opened to purge the inside of the piping 380 with nitrogen gas. The valve 269 is closed after the completion of the purge.

The valve 270 of the raw material replenishing cartridge 350, and the valve 267 are opened, and the solid raw material 400 within the bottle 351 of the raw material replenishing cartridge 350 is dropped and supplied into the solid raw material tank 300. The supplied solid raw material 400 is uniformly supplied to the central portion of the solid raw material tank 300 by the inclination portion 302 of the bottom 303 of the solid raw material tank 300. After the solid raw material 400 is supplied to the solid raw material tank 300, the space 304 is formed between the solid raw material 400 and the ceiling plate 310.

After the supply of the solid raw material 400 to the solid raw material tank 300 is ended, the valve 270 and the valve 267 are closed, the valve 268 is opened, and the inside of piping 380 is vacuumed by the vacuum pump 246 via the piping 259 and the exhaust pipe 231. Thereafter, the valve 268 is closed and the valve 269 is opened to purge the inside of the piping 380 with nitrogen gas. The valve 269 is closed after the completion of the purge.

Thereafter, the clamp 382 is removed, and the raw material replenishing cartridge 350 is removed from the piping 380. After the raw material replenishing cartridge 350 is removed from the piping 380, the closing plate 377 is fixed to the flange 368 of the piping 380 by the clamp 382 via the O ring 367 (refer to FIG. 10).

On the other hand, the removed raw material replenishing cartridge 350 is sent to a raw material supply maker, and the raw material replenishing cartridge 350 is filled with the next solid raw material 400.

### Second Embodiment

Next, the processing furnace 202, the raw material supply system 230, the exhaust system 240, and the like of a second embodiment to be used for the substrate processing apparatus 101 mentioned above with reference to FIG. 12 will be described. The processing furnace 202 and the exhaust system 240 of the present embodiment are the same as the processing furnace 202 and the exhaust system 240 of the first embodiment. The raw material supply system 230 of the present embodiment is different from the raw material supply system 230 of the first embodiment in that, in the first embodiment, the gas supply pipe 282 and the piping 283 are not provided with heaters, whereas in the present embodiment, the gas supply pipe 282 is provided with the heater 422 and the piping 283 is provided with the heater 423, but is the same as the raw material supply system 230 of the first embodiment in other points. Additionally, the process of forming GaN using the substrate processing apparatus 101 of the second embodiment is also the same as that of the first embodiment.

Next, the structure and replenishing method for replenishing the solid raw material tank 300 with the solid raw material 400 will be described.

Referring to FIGS. 12 to 15, the solid raw material tank 300 of the present embodiment is the same as the structure of the solid raw material tank 300 of the first embodiment. The piping 375 is connected to the through hole 316 of the solid raw material tank 300. The valve 267 is connected to the piping 375, the piping 380 is connected to the valve 267, and a raw material replenishing cartridge 470 for replenishing the solid raw material 400 is attached to the piping 380.

The flange 372 of the valve 267 is fixed to the flange 374 of the piping 375 by the clamp 384 via the O ring 373. The flange 369 of the piping 380 is fixed to the flange 371 of the valve 267 by the clamp 383 via the O ring 370. A flange 466 of a valve 480 of the raw material replenishing cartridge 470 is fixed to the flange 368 of the piping 380 by the clamp 382 via an O ring 367. The flange 368 of the piping 380 is located right above the through hole 316. The valve 267 and the valve 480 are manual valves.

The purge gas supply piping 284 and the piping 259 are connected to the piping 380. The purge gas supply piping 284 is provided with the valve 269. As a purge gas to be supplied to the purge gas supply piping 284, for example, nitrogen (N₂) gas or argon (Ar) gas is used. The piping 259 is connected to the exhaust pipe 231 on the downstream side of the vacuum pump 246 (refer to FIG. 12). The piping 259 is provided with the valve 268. The opening and closing operation of the valves 268 and 269 is controlled by the controller 280. The purge gas supply piping 284 is provided with a heater 425 and the piping 259 is provided with a heater 426.

One end of piping 494 is connected to the purge gas supply piping 284 on the upstream side of the valve 269. The piping 494 is provided with a valve 485. The other end of the piping 494 is provided with a joint 512. One end of piping 495 is connected to the piping 259 on the downstream side of the valve 268. The piping 495 is provided with a valve 487. The other end of the piping 495 is provided with a joint 511. Piping 493 is connected between the piping 494 between the valve 485 and the joint 512 and the piping 495 between the valve 487 and the joint 511. The piping 493 is provided with a valve 486.

In addition, the raw material supply system 230 includes not only the gas supply system 230a, the gas supply system 230b, the carrier gas supply system 230c, and the carrier gas supply system 230d but also the purge gas supply piping 284, the piping 259, and the valves 269 and 268 that are connected to the solid raw material tank 300.

The raw material replenishing cartridge 470 includes a container 471, the valve 480, a valve 483, and a valve 484. The container 471 includes a container body 472, and a piping portion 473 for container attachment under the container body. An upper end of the piping portion 473 for container attachment communicates with the container body 472. A lower end of the piping portion 473 for container attachment is provided with a flange 463. A flange 465 of the valve 480 is fixed to the flange 463 of the piping portion 473 for container attachment by a clamp 481 via an O ring 464.

Piping 491 is connected to the piping portion 473 for container attachment. The valve 483 is connected to the piping 491. Piping 492 is connected to an upper part of the container body 472. The valve 484 is connected to the piping 492.

A lid 474 is attached to the container body 472 with a screw 476. A sealing member (not shown), such as an O ring, is provided between the container body 472 and the lid 474. A window 475 is provided at the lid 474 so that the solid raw material 400 can be seen.

FIGS. 13 to 15 show a state where the raw material replenishing cartridge 470 is attached to the piping 380. As described above, the valve 480 of the raw material replenishing cartridge 470 is fixed to the piping 380 by the clamp 382. The valve 483 is connected to the joint 512 of the piping 494. The valve 484 is connected to the joint 511 of the piping 495.

FIGS. 16 to 20 show a state before the raw material replenishing cartridge 470 is attached to the piping 380 and after the raw material replenishing cartridge is removed from the piping 380. In addition, in the case of the removal, the solid raw material 400 does not remain within the container 471. Before the raw material replenishing cartridge 470 is attached to the piping 380 and after the raw material replenishing cartridge is removed from the piping, a closing plate 488 is fixed to the flange 466 of the valve 480 by a clamp 482 via an O ring 489. A closing cock 498 is attached to the valve 483, and a closing cock 499 is attached to the valve 484. Additionally, the closing plate 377 is fixed to the flange 368 of the piping 380 by the clamp 382 via the O ring 367. A closing cock 478 is attached to the joint 512 of the piping 494, and a closing cock 479 is attached to the joint 511 of the piping 495.

In the present embodiment, the respective members, such as the mass flow controllers 241, 242, 243, and 244, the valves 250, 251, 253, 254, 256, 261, 262, 263, 264, 265, 266, 268, 269, 483, 484, 485, 486, and 487, the APC valve 255, the heater 207, 281, 285, 421, 422, 423, 424, 425, 426, 450, 451, 452, and 453, the temperature sensor (not shown), the pressure sensor 245, the vacuum pump 246, the boat rotating mechanism 227, and the boat elevator 115, are connected to the controller 280. The controller 280 is an example of a control unit (control means) that controls the overall operation of the substrate processing apparatus 101, and is adapted to control the flow rate adjustment of the mass flow controllers 241, 242, 243, and 244, the opening and closing operation of the valves 250, 251, 253, 254, 256, 261, 262, 263, 264, 265, 266, 268, 269, 483, 484, 485, 486, and 487, a pressure adjustment operation based on the opening and closing of the APC valve 255 and the pressure sensor 245, the temperature adjustment operation of the heaters 281, 285, 421, 422, 423, 424, 425, 426, 450, 451, 452, and 453, the temperature adjustment operation of the heater 207 based on a temperature sensor (not shown), the start or stop of the vacuum pump 246, the rotating-speed regulation of the boat rotating mechanism 227, the elevation operation of a boat elevator 115, or the like, respectively. In addition, the valves 250, 251, 253, 254, 256, 261, 262, 263, 264, 265, 266, 268, 269, 483, 484, 485, 486, and 487 are air valves, and are controlled by the controller 280 via electromagnetic valves, respectively.

Next, a method of supplying or replenishing the solid raw material tank 300 with the solid raw material 400 using the raw material replenishing cartridge 470 will be described.

First, the operation when the substrate processing apparatus 101 is started will be described. When the substrate processing apparatus 101 is started, as shown in FIGS. 16 to 20, the raw material replenishing cartridge 470 is not attached to the piping 380. The closing plate 377 is attached to the flange 368 of the piping 380. The closing cock 478 is attached to the joint 512 of the piping 494, and the closing cock 479 is attached to the joint 511 of the piping 495. All the Valves 250, 251, 253, 254, 256, 261, 262, 263, 264, 265, 266, 268, 269, 483, 484, 485, 486, and 487 are closed, and all the heaters 281, 285, 421, 422, 423, 424, 425, 426, 450, 451, 452, and 453 are turned into an OFF state.

First, the valves 263, 264, 265, and 261 are opened to supply purge gas, such as nitrogen (N₂) gas or argon (Ar) gas, from the gas supply pipe 282 to purge an upper piping line of the solid raw material tank 300 via the solid raw material tank 300 and the gas supply pipe 232b. Further, the valves 268, 269, 485, 486, and 487 are opened to supply purge gas, such as nitrogen (N₂) gas or argon (Ar) gas from the purge gas supply piping 284 to purge an upper piping line of the valve 267. Thereafter, the heaters 281, 285, 421, 422, 423, 424, 425, 426, 450, 451, 452, and 453 are turned on to set the temperature of all the lines to 100° C. or higher to carry out moisture removal for 12 hours to 48 hours.

Thereafter, the heaters 450, 451, and 452 are controlled to set the temperature of the solid raw material tank 300 to a service temperature (40° C. to 150° C.), and a heater 453 and heaters 281, 285, 421, 422, 423, and 424 are controlled to set the temperature of the solid raw material tank 300 to 10° C. from the service temperature+5° C. via the valve 267, the gas supply pipe 282, the gas supply pipe 232b, the vent line 258, and the piping 283 and 375, and the heaters 424, 425, and 426 are turned off. The valves 265 and 261 are closed and the valves 266 and 262 are opened to supply purge gas, such as nitrogen (N₂) gas or argon (Ar) gas from the gas supply pipe 282 to carry out bypass-line purge via the gas supply pipe 282, the piping 283, and the vent line 258. Additionally, the valves 268 and 487 are closed to bring the upper piping line of the valve 267 into a pressurized state.

Next, the operation when the raw material replenishing cartridge 470 is attached will be described. Referring to FIGS. 16, 17, 19, and 20, the closing plate 488 attached to the valve 480 of the raw material replenishing cartridge 470 is removed, and the closing cock 499 attached to the closing cock 498 and valve 484 that are attached to the valve 483 is removed. Further, the closing plate 377 attached to the flange 368 of piping 380 is removed, and the closing cock 478 attached to the joint 512 of the piping 494 and the closing cock 479 attached to the joint 511 of the piping 495 are removed. Then, as shown in FIGS. 14 and 16, the raw material replenishing cartridge 470 is attached by attaching the valve 480 of the raw material replenishing cartridge 470 to the flange 368 of the piping 380, attaching the valve 483 to the joint 512 of the piping 494, and attaching the valve 484 to the joint 511 of the piping 495.

Next, with reference to FIGS. 13 to 15, the piping 380 between the valve 267 and valve 480, the purge gas supply piping 284 between the valve 269 and the piping 380, and the piping 259 between the valve 269 and the piping 380, which are opened to the atmosphere, are purged by repeating opening the valve 268 for 5 seconds and then closing this valve for 25 seconds, with the valve 269 opened, to carry out 15 cycles or more of purging.

Additionally, the valve 487 is opened, the valve 486 is closed, and the valves 485 and 483 are opened to supply purge gas, such as nitrogen (N₂) gas or argon (Ar) gas, from the purge gas supply piping 284 to purge the inside of the raw material replenishing cartridge 470, the piping 494, the valve 483, the piping 491, the piping 492, the valve 484, and the piping 495 to perform moisture removal. In this case, since the purge gas is introduced into the raw material replenishing cartridge 470 from the lower part of the raw material replenishing cartridge 470 via the piping 491, and the purge gas is discharged from the piping 492 attached to the upper part of the raw material replenishing cartridge 470, the moisture of the fixed raw material 400 of the raw material replenishing cartridge 470 is also removed by the purge gas.

The valves 269 and 268 are closed and brought into a raw material filling standby state. The valves 266 and 262 are closed and the valves 264 and 261 are opened to supply purge gas, such as nitrogen (N₂) gas or argon (Ar) gas, from the gas supply pipe 282 to carry out the purging within the solid raw material tank 300.

Thereafter, the valve 487 is closed and the valves 267 and 480 are opened to supply the solid raw material 400 to the solid raw material tank 300 from the raw material replenishing cartridge 470. Thereafter, the valve 267 is closed and the valves 269 and 268 is opened to perform purging.

Thereafter, the valve 487 is opened to purge the inside of the raw material replenishing cartridge 470. The valves 264 and 265 are closed and the valves 266 and 261 are opened to bring a process supply standby state.

The temperature of the heaters 424, 425, and 426 is set to 80° C., and the solid raw material 400 is filled into the solid raw material tank 300 from the raw material replenishing cartridge 470. After the passage of 12 hours after the filling, the valve 480 is closed, the valves 483 and 484 are closed, and the valve 486 is opened to stop the purging within the raw material replenishing cartridge 470. The valves 268 and 487 are closed to enclose the purge gas.

The valve 480 of the raw material replenishing cartridge 470 is removed from the flange 368 of the piping 380, the valve 483 is removed from the joint 512 of the piping 494, the valve 484 is removed from the joint 511 of the piping 495, and the raw material replenishing cartridge 470 is removed. The closing plate 488 is attached to the valve 480 of the raw material replenishing cartridge 470, the closing cock 498 is attached to the valve 483, and the closing cock 499 is attached to the valve 484. The closing plate 377 is attached to the flange 368 of the piping 380, the closing cock 478 is attached to the joint 512 of the piping 494, and the closing cock 479 is attached to the joint 511 of the piping 495. The valves 469 and 487 are opened to perform regular line purging.

Although the method of supplying the solid raw material 400 to the solid raw material tank 300 by attaching the raw material replenishing cartridge 470 to after the substrate processing apparatus 101 is started has been described as above. However, the same manipulation as the above is performed even when the solid raw material 400 is supplied to the solid raw material tank 300 by attaching the raw material replenishing cartridge 470 after the solid raw material 400 of the solid raw material tank 300 becomes empty.

Since the solid raw material 400 can be supplied to the solid raw material tank 300 with its moisture being 0.5 ppm or less by supplying the solid raw material 400 to the solid raw material tank 300 from the raw material replenishing cartridge 470 as described above, chloride gas and moisture can be sufficiently kept from reacting with each other, and it is possible to semipermanently supply the solid raw material 400 with no corrosion of the inside of the solid raw material tank 300.

Additionally, since the inside of the raw material replenishing cartridge 470 can be purged, it is possible to remove the moisture mixed at the time of the supply of the solid raw material 400 into the raw material replenishing cartridge 470.

A technique of removing the solid raw material tank to replenish the solid raw material for comparison will be described with reference to FIGS. 21 and 22. In this comparative example, a solid raw material tank 330 is used instead of the solid raw material tank 300 of the above embodiment. The valve 264 of the gas supply pipe 282 is connected to the solid raw material tank 330 via the valve 325, the joint 323, and the joint 321. Additionally, the valve 265 of the gas supply pipe 232b is connected to the solid raw material tank 330 via the valve 326, the joint 324, and the joint 322.

When the processing of the wafers 200, such as film formation, is performed, the solid raw material tank 330 stored as the solid raw material 400 is heated to a predetermined temperature, the valves 263, 264, 325, 326, 265, and 261 are opened to supply nitrogen (N₂) gas to the solid raw material tank 330 from the piping 282 as the carrier gas, and the solid raw material 400 turned into a gas is supplied to the gas supply pipe 232b along with the nitrogen gas.

If the solid raw material tank 330 becomes empty, the valves 264, 325, 326, and 265 are closed, the joints 323 and 324 are removed, and the solid raw material tank 330 is removed. Then, piping 282′ between the valve 264 and the joint 323 and piping 232b′ between the valve 265 and a joint 324 are opened to the atmosphere, and moisture or the like in atmosphere adheres to the piping 282′ and the piping 232b′. Therefore, in order to the remove the moisture of the piping 282′ between the valve 264 and the valve 325 and the piping 232b′ between the valve 265 and the valve 326 after an exchanged solid raw material tank 330 is attached, it is necessary to close valves 264, 265, and 261 and open the valves 263, 266, and 262 to introduce nitrogen (N₂) gas from the piping 282 and pass the nitrogen gas to the piping 258 to perform nitrogen gas purging, and there is a problem in that purging time becomes long.

Since the above-described preferable first and second embodiments of the invention has a structure in which the raw material replenishing cartridge 350 or 470 is attached to the piping 380, and the solid raw material 400 is supplied to the solid raw material tank 300 from the raw material replenishing cartridge 350 or 470, the configuration of the apparatus is also simple, and the solid raw material 400 can also be easily replenished. Additionally, the solid raw material 400 can be directly supplied the solid raw material tank 300 from the raw material replenishing cartridge 350 or 470. Moreover, it is not necessary to use solid raw material tanks for replenishment other than the solid raw material tank 300 unlike Japanese Patent Application Laid-Open (JP-A) No. 2010-40695.

Moreover, in the first and second preferable embodiments of the invention, it is not necessary to remove the solid raw material tank 300 when the solid raw material 400 is replenished. Since the solid raw material tank 300 is not removed, the piping is not opened to the atmosphere between the valve 265 and the solid raw material tank 300 and the piping is not opened to the atmosphere between the valve 264 and the solid raw material tank 300, and it is not necessary to perform purging for removal the moisture in these piping when the solid raw material 400 is replenished. Therefore, the replenishment time of the solid raw material 400 can be sharply shortened compared to the comparative example.

Additionally, the piping 259 connected to the vacuum pump 246 is connected to the piping 380, the purge gas supply piping 284 that supplies purge gas for purging is connected to the piping 380, and the piping is provided with the valves 270 (480) or 267. Thus, after the raw material replenishing cartridge 350 or and 470 is attached to the piping 380, the inside of the piping 380 can be vacuumed and the nitrogen gas purging can then be performed. Accordingly, the solid raw material tank 300 can be replenished with the solid raw material 400 from the raw material replenishing cartridge 350 or 470 in a state where the inside of the piping 380 is turned into a nitrogen gas atmosphere. As a result, the inside of the solid raw material tank 300 is not exposed to an air atmosphere when the solid raw material 400 is replenished.

Since the bottom 303 of the solid raw material tank 300 is provided with the inclination portion 302 with a low center and a high peripheral portion, even if the replenished solid raw material 400 is supplied not from the center of the solid raw material tank 300 but from an end, it is easy to uniformly move the raw material to the central portion by the inclination portion 302.

In addition, although the method of forming a GaN film by the ALD method has been described above as an example, forming a film or forming a GaN film by the ALD method is merely an example. A film may be formed by other methods, for example, a CVD method, and other films, for example, an AlN film may be formed.

Additionally, although GaCl₃ of the solid raw material is used above, TMGa (trimethyl gallium) or TMAl (trimethyl aluminum) can also be used. These are suitably used for film formation of GaN and AlN.

(Preferable Aspect of the Invention)

Preferable aspects of the invention will be described.

(Additional Remark 1)

According to one preferable aspect of the present invention, there is provided

a substrate processing apparatus including:

a processing chamber capable of accommodating a substrate;

a raw material supply system that sublimates a solid raw material to generate a gas raw material used for processing of the substrate, and supplies the generated gas raw material to the processing chamber; and

a control unit, wherein

the raw material supply system includes:

a solid raw material container that stores the solid raw material;

a first piping connected between the solid raw material container and the processing chamber;

a second piping connected with the solid raw material container and equipped with an attachment portion to which a raw material replenishing container that holds the solid raw material for replenishment is attached;

a third piping connected between the second piping and an evacuation unit; and

a fourth piping connected with the second piping to introduce purge gas;

a first valve connected in the middle of the third piping; and

a second valve connected in the middle of the fourth piping, wherein the control unit is configured to control the evacuation unit, the first valve, and the second valve so as to vacuum the inside of the second piping and then introduce the purge gas into the second piping, when the raw material replenishing container is attached to the attachment portion in order to replenish the solid raw material to the solid raw material container from the raw material replenishing container.

(Additional Remark 2)

The substrate processing apparatus of Additional Remark 1, preferably, further includes a raw material replenishing container purge gas introducing portion attachment portion to which a purge gas introducing portion of the raw material replenishing container that introduces purge gas into the raw material replenishing container is attached, and a raw material replenishing container purge gas discharge portion attachment portion to which a purge gas discharge portion of the raw material replenishing container that discharges purge gas from the raw material replenishing container is attached, and

wherein the control unit is configured to control the evacuation unit, the first valve and the second valve so as to vacuum the inside of the second piping and then introduce the purge gas into the second piping when the raw material replenishing container is attached to the attachment portion in order to replenish the solid raw material to the solid raw material container from the raw material replenishing container, the purge gas introducing portion of the raw material replenishing container is attached to the raw material replenishing container purge gas introducing portion attachment portion, and the purge gas discharge portion of the raw material replenishing container is attached to the raw material replenishing container purge gas discharge portion attachment portion, and to control the evacuation unit, the first valve, the second valve, the purge gas introducing portion, and the purge gas discharge portion so as to introduce the purge gas into the raw material replenishing container from the purge gas introducing portion of the raw material replenishing container and discharge the purge gas from the purge gas discharge portion of the raw material replenishing container.

(Additional Remark 3)

In the substrate processing apparatus of Additional Remark 2, preferably, the purge gas introducing portion of the raw material replenishing container is connected to a lower part of the raw material replenishing container when the raw material replenishing container is attached to the attachment portion, and the purge gas discharge portion of the raw material replenishing container is connected to an upper part of the raw material replenishing container when the raw material replenishing container is attached to the attachment portion.

(Additional Remark 4)

The substrate processing apparatus of any of Additional Remarks 1 to 3 preferably includes a third valve provided between the second piping and the solid raw material container.

(Additional Remark 5)

In the substrate processing apparatus of any of Additional Remarks 1 to 4, preferably, the second piping is connected to a ceiling portion of the solid raw material container.

(Additional Remark 6)

In the substrate processing apparatus of any of Additional Remarks 1 to 5, preferably, the solid raw material container includes an inclination portion with a low center and a high peripheral portion at a bottom inside the container.

(Additional Remark 7)

According to another preferable aspect of the present invention, there is provided

a solid raw material replenishing method including:

attaching a raw material replenishing container to an attachment portion of a raw material supply system; wherein the raw material supply system sublimates a solid raw material to generate a gas raw material used for processing of a substrate, and supplies the generated gas raw material to a processing chamber that processes the substrate, and wherein the raw material supply system includes: a solid raw material container that stores the solid raw material; a first piping connected between the solid raw material container and the processing chamber; a second piping connected with the solid raw material container and equipped with an attachment portion to which the raw material replenishing container that holds the solid raw material for replenishment is attached; a third piping connected between the second piping and an evacuation means; a fourth piping connected with the second piping to introduce purge gas; a first valve connected in the middle of the third piping; and a second valve connected in the middle of the fourth piping;

closing the second valve, opening the first valve, and vacuuming the inside of the second piping with the evacuation unit, in a state where the raw material replenishing container is attached to the attachment portion;

then closing the first valve, opening the second valve, and introducing the purge gas within the second piping; and

then replenishing the solid raw material via the second piping to the solid raw material container from the raw material replenishing container.

(Additional Remark 8)

The solid raw material replenishing method of Additional Remark 7, preferably, further includes:

attaching a purge gas introducing portion of the raw material replenishing container that introduces the purge gas into the raw material replenishing container to a raw material replenishing container purge gas introducing portion attachment portion of the raw material supply system, and attaching a purge gas discharge portion of the raw material replenishing container that discharges the purge gas from the raw material replenishing container, to the raw material replenishing container purge gas discharge portion attachment portion of the raw material supply system; and

then introducing the purge gas into the raw material replenishing container from a purge gas introducing portion of the raw material replenishing container, and discharging the purge gas from the purge gas discharge portion of the raw material replenishing container, before the solid raw material container is replenished with the solid raw material via the second piping from the raw material replenishing container.

(Additional Remark 9)

In the solid raw material replenishing method of Additional Remark 8, preferably, the purge gas introducing portion of the raw material replenishing container is connected to a lower part of the raw material replenishing container when the raw material replenishing container is attached to the attachment portion, and the purge gas discharge portion of the raw material replenishing container is connected to an upper part of the raw material replenishing container when the raw material replenishing container is attached to the attachment portion.

(Additional Remark 10)

In the solid raw material replenishing method of Additional Remark 8 or 9, preferably, the raw material supply system includes a third valve provided between the second piping and the solid raw material container, and the third valve is closed in the attaching of the raw material replenishing container, the vacuuming, and the introducing of the purge gas, and the third valve is opened in the replenishing of the solid raw material.

(Additional Remark 11)

In the solid raw material replenishing method of any one of Additional Remarks 8 to 10, preferably, the raw material replenishing container includes a fourth valve, and the raw material replenishing container is attached to the attachment portion via the fourth valve, the fourth valve is closed in the attaching of the raw material replenishing container, the vacuuming, and the introducing of the purge gas, and the fourth valve is opened in the replenishing of the solid raw material.

(Additional Remark 12)

In the solid raw material replenishing method of any one of Additional Remarks 8 to 11, preferably, the second piping is connected with a ceiling portion of the solid raw material container, and the solid raw material is dropped into the solid raw material container from the raw material replenishing container in the replenishing of the solid raw material.

(Additional Remark 13)

In the solid raw material replenishing method of any one of Additional Remarks 8 to 12, preferably, the solid raw material container includes an inclination portion with a low center and a high peripheral portion at a bottom inside the container.

(Additional Remark 14)

According to a still another preferable aspect of the invention, there is provided

a substrate processing apparatus including:

a processing chamber capable of accommodating a substrate; and

a raw material supply system that sublimates a solid raw material to generate a gas raw material used for processing of the substrate, and supplies the generated gas raw material to the processing chamber; wherein

the raw material supply system includes:

a solid raw material container that stores the solid raw material;

a first piping connected between the solid raw material container and the processing chamber;

a second piping connected with the solid raw material container and equipped with an attachment portion to which a raw material replenishing container that holds the solid raw material for replenishment is attached.

(Additional Remark 15)

In the substrate processing apparatus of Additional Remark 14, preferably, the second piping is connected to a ceiling portion of the solid raw material container.

(Additional Remark 16)

In the substrate processing apparatus of Additional Remark 15, preferably, the attachment portion is located right above a place where the second piping is connected to a ceiling portion of the solid raw material container.

(Additional Remark 17)

The substrate processing apparatus of any one of Additional Remarks 14 to 16 preferably includes a first valve provided between the second piping and the solid raw material container.

(Additional Remark 18)

In the substrate processing apparatus of any one of Additional Remarks 14 to 17, preferably, the solid raw material container includes an inclination portion with a low center and a high peripheral portion at a bottom inside the container.

(Additional Remark 19)

The substrate processing apparatus of any of Additional Remarks 14 to 18 preferably further includes a third piping connected between the second piping, and an evacuation means, and a fourth piping connected with the second piping to introduce purge gas.

(Additional Remark 20)

According to a still further preferable aspect of the present invention, there is provided

a solid raw material replenishing method including:

attaching a raw material replenishing container to an attachment portion of a raw material supply system, wherein the raw material supply system sublimates a solid raw material to generate a gas raw material used for processing of the substrate, and supplies the generated gas raw material to a processing chamber that processes the substrate, and wherein the raw material supply system includes: a solid raw material container that stores the solid raw material; a first piping connected between the solid raw material container and the processing chamber; and a second piping connected with the solid raw material container and equipped with an attachment portion to which the raw material replenishing container that holds the solid raw material for replenishment is attached; and

replenishing the solid raw material via the second piping to the solid raw material container from the raw material replenishing container in a state where the raw material replenishing container is attached to the attachment portion.

(Additional Remark 21)

In the solid raw material replenishing method of Additional Remark 20, preferably, the second piping is connected with a ceiling portion of the solid raw material container, and the solid raw material is dropped and replenished into the solid raw material container from the raw material replenishing container in the replenishing of the solid raw material via the second piping.

(Additional Remark 22)

In the solid raw material replenishing method of Additional Remark 20 or 21, preferably, the attachment portion is located right above a place where the second piping is connected to a ceiling portion of the solid raw material container.

(Additional Remark 23)

The solid raw material replenishing method of any one of Additional Remarks 20 to 22 preferably includes a first valve provided between the second piping and the solid raw material container, and the first valve is opened in the replenishing of the solid raw material.

(Additional Remark 24)

In the solid raw material replenishing method of any one of Additional Remarks 20 to 23, preferably, the raw material replenishing container includes a second valve, the raw material replenishing container is attached to the attachment portion via the second valve, and the second valve is opened in the replenishing of the solid raw material.

(Additional Remark 25)

In the solid raw material replenishing method of any one of Additional Remarks 20 to 24, preferably, the solid raw material container includes an inclination portion with a low center and a high peripheral portion at a bottom inside the container.

(Additional Remark 26)

According to a still further preferable aspect of the present invention, there is provided

a substrate processing apparatus including:

a processing chamber capable of accommodating a substrate; and

a raw material supply system that sublimates a solid raw material to generate a gas raw material used for processing of the substrate, and supplies the generated gas raw material to a processing chamber; wherein

the raw material supply system includes:

a solid raw material container that stores the solid raw material;

a first piping connected between the solid raw material container and the processing chamber;

an attachment portion in which a raw material replenishing container that holds the solid raw material for replenishment is attached to the solid raw material container;

a raw material replenishing container purge gas introducing portion attachment portion to which a purge gas introducing portion of a raw material replenishing container that introduces purge gas into the raw material replenishing container is attached, and

a raw material replenishing container purge gas discharge portion attachment portion to which a purge gas discharge portion of the raw material replenishing container that discharges purge gas from the raw material replenishing container is attached; and

a control unit configured to control the purge gas introducing portion and the purge gas discharge portion so as to introduce the purge gas into the raw material replenishing container from the purge gas introducing portion of the raw material replenishing container and discharge the purge gas from the purge gas discharge portion of the raw material replenishing container when the raw material replenishing container is attached to the attachment portion in order to replenish the solid raw material to the solid raw material container from the raw material replenishing container, the purge gas introducing portion of the raw material replenishing container is attached to the raw material replenishing container purge gas introducing portion attachment portion, and the purge gas discharge portion of the raw material replenishing container is attached to the raw material replenishing container purge gas discharge portion attachment portion.

(Additional Remark 27)

In the substrate processing apparatus of Additional Remark 26, preferably, the purge gas introducing portion of the raw material replenishing container is connected to a lower part of the raw material replenishing container when the raw material replenishing container is attached to the attachment portion, and the purge gas discharge portion of the raw material replenishing container is connected to an upper part of the raw material replenishing container when the raw material replenishing container is attached to the attachment portion.

(Additional Remark 28)

In the substrate processing apparatus of Additional Remark 27, preferably, the purge gas introducing portion of the raw material replenishing container includes a second piping connected to a lower part of the raw material replenishing container when the raw material replenishing container is attached to the attachment portion, and a first valve provided in the second piping, and the purge gas discharge portion of the raw material replenishing container includes a third piping connected to an upper part of the raw material replenishing container when the raw material replenishing container is attached to the attachment portion, and a second valve provided in the third piping.

(Additional Remark 29)

According to a still further preferable aspect of the invention, there is provided

a solid raw material replenishing method including:

attaching a raw material replenishing container to an attachment portion of a raw material supply system, wherein the raw material supply system sublimates a solid raw material to generate a gas raw material used for processing of the substrate, and supplies the generated gas raw material to a processing chamber that processes the substrate; and wherein the raw material supply system includes: a solid raw material container that stores the solid raw material; a first piping connected between the solid raw material container and the processing chamber; an attachment portion in which a raw material replenishing container that holds the solid raw material for replenishment is attached to the solid raw material container; a raw material replenishing container purge gas introducing portion attachment portion to which a purge gas introducing portion of the raw material replenishing container that introduces purge gas into the raw material replenishing container is attached; and a raw material replenishing container purge gas discharge portion attachment portion to which a purge gas discharge portion of the raw material replenishing container that discharges purge gas from the raw material replenishing container is attached;

attaching a purge gas introducing portion of the raw material replenishing container that introduces purge gas into the raw material replenishing container to a raw material replenishing container purge gas introducing portion attachment portion of the raw material supply system, and

attaching a purge gas discharge portion of the raw material replenishing container that discharges purge gas from the raw material replenishing container to a raw material replenishing container purge gas discharge portion attachment portion of the raw material supply system;

then introducing the purge gas into the raw material replenishing container from the purge gas introducing portion of the raw material replenishing container, and discharging the purge gas from the purge gas discharge portion of the raw material replenishing container; and

then replenishing the solid raw material to the solid raw material container from the raw material replenishing container in a state where the raw material replenishing container is attached to the attachment portion.

(Additional Remark 30)

In the solid raw material replenishing method of Additional Remark 29, preferably, the purge gas introducing portion of the raw material replenishing container is connected to a lower part of the raw material replenishing container when the raw material replenishing container is attached to the attachment portion, and the purge gas discharge portion of the raw material replenishing container is connected to an upper part of the raw material replenishing container when the raw material replenishing container is attached to the attachment portion.

(Additional Remark 31)

According to a still further preferable aspect of the invention,

there is provided a cartridge for replenishing a solid raw material including a solid raw material storage container, and an exhaust valve attached to an opening portion of the container.

(Additional Remark 32)

According to a still another preferable aspect of the invention, there is provided

a cartridge for replenishing a solid raw material including:

a solid raw material storage container;

an attachment portion that attaches the solid raw material storage container;

a purge gas introducing portion that introduces purge gas into the raw material replenishing container; and

a purge gas discharge portion that discharges the purge gas from the raw material replenishing container.

(Additional Remark 33)

In the cartridge of Additional Remark 32, preferably, the purge gas introducing portion of the raw material replenishing container is connected to a lower part of the raw material replenishing container when the raw material replenishing container is attached, and the purge gas discharge portion of the raw material replenishing container is connected to an upper part of the raw material replenishing container when the raw material replenishing container is attached.

(Additional Remark 34)

In the cartridge of Additional Remark 33, preferably, the purge gas introducing portion includes first piping connected to a lower part of the raw material replenishing container when the raw material replenishing container is attached, and a first valve provided in the first piping, and the purge gas discharge portion includes second piping connected to an upper part of the raw material replenishing container when the raw material replenishing container is attached, and a second valve provided in the second piping.

Although the various typical embodiments of the invention have been described above, the invention is not limited to these embodiments. Accordingly, the scope of the invention is limited by only the following claims.

What is claimed is:

1. A substrate processing apparatus, comprising:
a processing chamber that accommodates a substrate; and
a raw material supply system that sublimates a solid raw material to generate a gas raw material used for processing of the substrate, and supplies the generated gas raw material to the processing chamber, wherein
the raw material supply system includes:
a solid raw material container that stores the solid raw material;
a first piping connected between the solid raw material container and the processing chamber; and
a second piping connected with the solid raw material container and equipped with an attachment portion to which a raw material replenishing container that holds the solid raw material for replenishment is attached.

2. The substrate processing apparatus according to claim 1, further comprising:
a control unit,
a third piping connected between the second piping and an evacuation unit; and
a fourth piping connected with the second piping to introduce purge gas;
a first valve connected in the middle of the third piping; and
a second valve connected in the middle of the fourth piping, wherein
the control unit is configured to control the evacuation unit, the first valve, and the second valve so as to vacuum the inside of the second piping and then introduce the purge gas into the second piping, when the raw material replenishing container is attached to the attachment portion in order to replenish the solid raw material to the solid raw material container from the raw material replenishing container.

3. The substrate processing apparatus according to claim 2, further comprising:
a raw material replenishing container purge gas introducing portion attachment portion to which a purge gas introducing portion of the raw material replenishing container that introduces purge gas into the raw material replenishing container is attached; and
a raw material replenishing container purge gas discharge portion attachment portion to which a purge gas discharge portion of the raw material replenishing container that discharges purge gas from the raw material replenishing container is attached, wherein
the control unit is configured to control the evacuation unit, the first valve and the second valve so as to vacuum the inside of the second piping and then introduce the purge gas into the second piping when the raw material replenishing container is attached to the attachment portion in order to replenish the solid raw material to the solid raw material container from the raw material replenishing container, the purge gas introducing portion of the raw material replenishing container is attached to the raw material replenishing container purge gas introducing portion attachment portion, and the purge gas discharge portion of the raw material replenishing container is attached to the raw material replenishing container purge gas discharge portion attachment portion, and to control the evacuation unit, the first valve, the second valve, the purge gas introducing portion, and the purge gas discharge portion so as to introduce the purge gas into the raw material replenishing container from the purge gas introducing portion of the raw material replenishing container and discharge the purge gas from the purge gas discharge portion of the raw material replenishing container.

4. A substrate processing apparatus, comprising:
a processing chamber that accommodates a substrate; and
a raw material supply system that sublimates a solid raw material to generate a gas raw material used for processing of the substrate, and supplies the generated gas raw material to a processing chamber; wherein
the raw material supply system includes:
a solid raw material container that stores the solid raw material;
a first piping connected between the solid raw material container and the processing chamber;
an attachment portion in which a raw material replenishing container that holds the solid raw material for replenishment is attached to the solid raw material container;
a raw material replenishing container purge gas introducing portion attachment portion to which a purge gas introducing portion of a raw material replenishing container that introduces purge gas into the raw material replenishing container is attached; and
a raw material replenishing container purge gas discharge portion attachment portion to which a purge gas discharge portion of the raw material replenishing container that discharges purge gas from the raw material replenishing container is attached; and
a control unit configured to control the purge gas introducing portion and the purge gas discharge portion so as to introduce the purge gas into the raw material replenishing container from the purge gas introducing portion of the raw material replenishing container and discharge the purge gas from the purge gas discharge portion of the raw material replenishing container when the raw material replenishing container is attached to the attachment portion in order to replenish the solid raw material to the solid raw material container from the raw material replenishing container, the purge gas introducing portion of the raw material replenishing container is attached to the raw material replenishing container purge gas introducing portion attachment portion, and the purge gas discharge portion of the raw material replenishing container is attached to the raw material replenishing container purge gas discharge portion attachment portion.

5. A solid raw material replenishing method, comprising:
attaching a raw material replenishing container to an attachment portion of a raw material supply system; wherein the raw material supply system sublimates a solid raw material to generate a gas raw material used for processing of a substrate, and supplies the generated gas raw material to a processing chamber that processes the substrate, and wherein the raw material supply system includes: a solid raw material container that stores the solid raw material; a first piping connected between the solid raw material container and the processing chamber; a second piping connected with the solid raw material container and equipped with an attachment portion to which the raw material replenishing container that holds the solid raw material for replenishment is attached; a third piping connected between the second piping and an evacuation means; a fourth piping connected with the second piping to introduce purge gas; a first valve connected in the middle of the third piping; and a second valve connected in the middle of the fourth piping;
closing the second valve, opening the first valve, and vacuuming the inside of the second piping with the evacuation unit, in a state where the raw material replenishing container is attached to the attachment portion;
thereafter closing the first valve, opening the second valve, and introducing the purge gas within the second piping; and
thereafter replenishing the solid raw material via the second piping to the solid raw material container from the raw material replenishing container.

6. The solid raw material replenishing method according to claim 5, further comprising:
attaching a purge gas introducing portion of the raw material replenishing container that introduces the purge gas into the raw material replenishing container to a raw material replenishing container purge gas introducing portion attachment portion of the raw material supply system, and attaching a purge gas discharge portion of the raw material replenishing container that discharges the purge gas from the raw material replenishing container, to the raw material replenishing container purge gas discharge portion attachment portion of the raw material supply system; and
thereafter introducing the purge gas into the raw material replenishing container from a purge gas introducing portion of the raw material replenishing container, and discharging the purge gas from the purge gas discharge portion of the raw material replenishing container, before the solid raw material container is replenished with the solid raw material via the second piping from the raw material replenishing container.

7. A solid raw material replenishing method, comprising:
attaching a raw material replenishing container to an attachment portion of a raw material supply system, wherein the raw material supply system sublimates a solid raw material to generate a gas raw material used for processing of the substrate, and supplies the generated gas raw material to a processing chamber that processes the substrate; and wherein the raw material supply system includes: a solid raw material container that stores the solid raw material; a first piping connected between the solid raw material container and the processing chamber; an attachment portion in which a raw material replenishing container that holds the solid raw material for replenishment is attached to the solid raw material container; a raw material replenishing container purge gas introducing portion attachment portion to which a purge gas introducing portion of the raw material replenishing container that introduces purge gas into the raw material replenishing container is attached; and a raw material replenishing container purge gas discharge portion attachment portion to which a purge gas discharge portion of the raw material replenishing container that discharges purge gas from the raw material replenishing container is attached;
attaching a purge gas introducing portion of the raw material replenishing container that introduces purge gas into the raw material replenishing container to a raw material replenishing container purge gas introducing portion attachment portion of the raw material supply system, and
attaching a purge gas discharge portion of the raw material replenishing container that discharges purge gas from the raw material replenishing container to a raw material replenishing container purge gas discharge portion attachment portion of the raw material supply system;
thereafter introducing the purge gas into the raw material replenishing container from the purge gas introducing portion of the raw material replenishing container, and discharging the purge gas from the purge gas discharge portion of the raw material replenishing container; and
thereafter replenishing the solid raw material to the solid raw material container from the raw material replenishing container in a state where the raw material replenishing container is attached to the attachment portion.
